(19) United States
(12) Patent Application Publication
(10) Pub. No.: US 2026/0279277 A1
(43) Pub. Date: Sep. 17, 2026

(54) Array Substrate, Display Panel, and Display Device

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Tinghua Shang, Beijing (CN); Haigang Qing, Beijing (CN)

(21) Appl. No.: 18/996,476

(22) PCT Filed: Apr. 17, 2024
(86) PCT No.: PCT/CN2024/088425

§ 371 Date: Jan. 17, 2025

(30) Foreign Application Priority Data
May 29, 2023 (CN) 202310621415.X

(51) Int. Cl. G09G 3/3233

(52) U.S. Cl. CPC G09G 3/3233; G09G 2300/0426; G09G 2300/0842; G09G 2300/0861; G09G 2310/08; G09G 2320/0209; G09G 2320/0233

(57) ABSTRACT

An array substrate, including: a substrate; a plurality of pixel driving circuits, located at a side of the substrate, and arranged in multiple rows and multiple columns; a pixel driving circuit includes a compensation transistor, a driving transitory and a first conductive connection portion, where a control electrode of the driving transistor and a second electrode of the compensation transistor are both electrically connected to the first conductive connection portion; a plurality of first scanning signal lines, located at a side of the substrate, where the plurality of first scanning signal lines are extended along a row direction and are sequentially arranged along a column direction; a first scanning signal line is electrically connected to control electrodes of compensation transistors of a row of pixel driving circuits; the first conductive connection portion and the first scanning signal line do not overlap in a direction perpendicular to the substrate.

### CROSS-REFERENCE TO RELATED APPLICATIONS

This application is the United States national phase of International Patent Application No. PCT/CN2024/088425, filed Apr. 17, 2024, and claims priority to Chinese Patent Application No. 202310621415.X, filed May 29, 2023, the disclosures of which are hereby incorporated by reference in their entireties.

### BACKGROUND OF THE INVENTION

### Field of the Invention

The present disclosure relates to the field of display technologies, and in particular to an array substrate, a display panel and a display device.

### Description of Related Art

At present, an organic light-emitting diode (OLED) display device has been widely used due to its characteristics of self-luminescence, fast response, wide viewing angle and capable of being fabricated on a flexible substrate. An OLED display device includes a plurality of sub-pixels, where each sub-pixel of the plurality of sub-pixels includes a pixel driving circuit and a light-emitting device. The light-emitting device is driven by the pixel driving circuit to emit light, thereby realizing display.

### SUMMARY OF THE INVENTION

In an aspect, an array substrate is provided. The array substrate includes a substrate, a plurality of pixel driving circuits and a plurality of first scanning signal lines. The plurality of pixel driving circuits are located at a side of the substrate, and arranged in multiple rows and multiple columns. A pixel driving circuit of the plurality of pixel driving circuits includes a compensation transistor, a driving transistor and a first conductive connection portion, where a control electrode of the driving transistor and a second electrode of the compensation transistor are both electrically connected to the first conductive connection portion. The plurality of first scanning signal lines are located at a side of the substrate, the plurality of first scanning signal lines all extend along a row direction and are sequentially arranged along a column direction, the row direction and the column direction are parallel to the substrate and cross-arranged; a first scanning signal line of the plurality of first scanning signal lines is electrically connected to control electrodes of compensation transistors of a row of pixel driving circuits. Herein, the first conductive connection portion and the first scanning signal line do not overlap in a direction perpendicular to the substrate.

In some embodiments, the pixel driving circuit further includes: a data writing transistor and a first light-emitting control transistor, where a second electrode of the data writing transistor is electrically connected to a first electrode of the driving transistor and a second electrode of the first light-emitting control transistor. The array substrate further includes: a plurality of second scanning signal lines and a plurality of light-emitting control signal lines, located at a side of the substrate; the plurality of second scanning signal lines all extend along the row direction and are sequentially arranged along the column direction, and a second scanning signal line of plurality of second scanning signal lines is electrically connected to control electrodes of data writing transistors of the row of pixel driving circuits; the plurality of light-emitting control signal lines all extend along the row direction and are sequentially arranged along the column direction, and a light-emitting control signal line of the plurality of light-emitting control signal lines is electrically connected to control electrodes of first light-emitting control transistors of the row of pixel driving circuits. The array substrate further includes: a plurality of row pixel regions, where the plurality of row pixel regions extend along the row direction and are sequentially disposed along the column direction; a row of pixel driving circuits are disposed within a row pixel region of the plurality of row pixel regions, and a first scanning signal line, a second scanning signal line and a light-emitting control signal line electrically connected to the row of pixel driving circuit are located in the row pixel region where the row of pixel driving circuits are located. where in the row pixel region, the orthogonal projection of the first scanning signal line on the substrate is located on a side of an orthogonal projection of the second scanning signal line on the substrate away from an orthogonal projection of the light-emitting control signal line on the substrate, and an orthographic projection of the driving transistor on the substrate is located between the orthographic projection of the second scanning signal line on the substrate and the orthographic projection of the light-emitting control signal line on the substrate.

In some embodiments, in the row pixel region, the compensation transistor and the first conductive connection portion are sequentially disposed along the column direction; where the compensation transistor passes through the first scanning signal line, and the orthographic projection of the second electrode of the compensation transistor on the substrate is located at a side of the orthographic projection of the first scanning signal line on the substrate close to the orthographic projection of the light-emitting control signal line on the substrate, where the first conductive connection portion is located at a side of the first scanning signal line close to the light-emitting control signal line.

In some embodiments, in the row pixel region, a portion of an orthographic projection of the data writing transistor on the substrate is disposed opposite to an orthographic projection of the compensation transistor on the substrate in the row direction, and another portion of the orthographic projection of the data writing transistor on the substrate is disposed opposite to an orthographic projection of the first conductive connection portion on the substrate in the row direction.

In some embodiments, the data writing transistor passes through the second scanning signal line, and the data writing transistor is located at a side of the first scanning signal line close to the light-emitting control signal line. The array substrate further includes: a plurality of data transfer portions, where the plurality of data transfer portions are located at a side of the plurality of pixel driving circuits away from the substrate. The array substrate further includes: a plurality of data lines, where the plurality of data lines is located at a side of the plurality of data transfer portions away from the substrate, the plurality of data lines extend along the column direction and are sequentially arranged along the row direction, and a data line of the plurality of data lines is electrically connected to first electrodes of data writing transistors of the row of pixel driving circuits through a data transfer portion of the plurality of data transfer portions. Herein in a row pixel region, an orthographic projection of a data transfer portion on the substrate is located between the orthographic projection of the first scanning signal line on the substrate and the orthographic projection of the second scanning signal line on the substrate.

In some embodiments, in the row pixel region, a portion of an orthographic projection of the first conductive connection portion on the substrate overlaps with a portion of an orthographic projection of the compensation transistor on the substrate, and another portion of the orthographic projection of the first conductive connection portion on the substrate overlaps with a portion of the orthographic projection of the driving transistor on the substrate.

In some embodiments, the pixel driving circuit further includes a second conductive connection portion, where the second conductive connection portion is electrically connected to the first electrode of the driving transistor, the second electrode of the first light-emitting control transistor, and a second electrode of the data writing transistor. An orthographic projection of the second conductive connection portion on the substrate does not overlap with an orthographic projection of the first scanning signal line on the substrate.

In some embodiments, the pixel circuit further includes a third reset transistor, where a first electrode of the third reset transistor is electrically connected to the second conductive connection portion. The array substrate further includes: a plurality of second reset signal lines, where the plurality of second reset signal lines are located at a side of the plurality of pixel driving circuits away from the substrate, the plurality of second reset signal lines all extend along the row direction and are sequentially arranged along the column direction, and a second reset signal line of the plurality of second reset signal lines is electrically connected to control electrodes of third reset transistors of the row of pixel driving circuits; the second reset signal line electrically connected to the row of pixel driving circuits is located in a row pixel region where the row of pixel driving circuits are located. Herein, in the row pixel region, the second reset signal line is located at a side of the light-emitting control signal line away from the first scanning signal line.

In some embodiments, the array substrate further includes: a plurality of third initialization signal lines, where the plurality of third initialization signal lines are located at a side of the substrate; the plurality of third initialization signal lines all extend along the row direction and are sequentially arranged along the column direction, and a third initialization signal line of the plurality of third initialization signal lines is electrically connected to first electrodes of third reset transistors of the row of pixel driving circuits. In the row pixel region, an orthographic projection of the third initialization signal line on the substrate at least partially overlaps with an orthographic projection of the light-emitting control signal line on the substrate.

In some embodiments, in the row pixel region, the third reset transistor passes through the second reset signal line and is located at a side of the third initialization signal line away from the light-emitting control signal line; where an orthographic projection of the first electrode of the third reset transistor on the substrate is located between the orthographic projection of the third initialization signal line on the substrate and an orthographic projection of the second reset signal line on the substrate, and an orthographic projection of a second electrode of the third reset transistor on the substrate is located at a side of the orthographic projection of the second reset signal line on the substrate away from the orthographic projection of the third initialization signal line on the substrate. The second conductive connection portion crosses over the third initialization signal line, the light-emitting control signal line, and the second reset signal line, and is electrically connected to the second electrode of the third reset transistor.

In some embodiments, a portion of the orthographic projection of the second conductive connection portion on the substrate overlaps with an orthographic projection of the second electrode, a control electrode, and a portion of the first electrode of the third reset transistor on the substrate.

In some embodiments, the pixel driving circuit further includes a second light-emitting control transistor and a second reset transistor; a first electrode of the second light-emitting control transistor is electrically connected to a second electrode of the driving transistor and a first electrode of the compensation transistor, and a second electrode of the second light-emitting control transistor is electrically connected to a light-emitting device and a second electrode of the second reset transistor; where control electrodes of second light-emitting control transistors of the row of pixel driving circuits are electrically connected to the light-emitting control signal line, and control electrodes of second reset transistors of the row of pixel driving circuits are electrically connected to the second reset signal line. The array substrate further includes: a plurality of second initialization signal lines, where the plurality of second initialization signal lines are located at a side of the plurality of pixel driving circuits away from the substrate, the plurality of second initialization signal lines extend along the row direction, and are sequentially arranged along the column direction; a second initialization signal line of the plurality of second initialization signal lines is electrically connected to first electrodes of second reset transistors of the row of pixel driving circuits. Herein, in a row pixel region, an orthographic projection of the second initialization signal line on the substrate is located at a side of an orthographic projection of the second reset signal line on the substrate away from the orthographic projection of the first scanning signal line on the substrate.

In some embodiments, the pixel driving circuit further includes: a first reset transistor and a third conductive connection portion, where the third conductive connection portion is electrically connected to a second electrode of the first reset transistor, the second electrode of the driving transistor and the first electrode of the compensation transistor. The array substrate further includes: a plurality of first reset signal lines, where the plurality of first reset signal lines are located at a side of the plurality of pixel driving circuits away from the substrate, the plurality of first reset signal line all extend along the row direction and are sequentially arranged along the column direction, and a first reset signal line of the plurality of first reset signal lines is electrically connected to control electrodes of first reset transistors of a row of pixel driving circuits. Herein, in the row pixel region, an orthographic projection of the first reset signal line on the substrate is located at a side of an orthographic projection of the light-emitting control signal line on the substrate away from the orthographic projection of the first scanning signal line on the substrate.

In some embodiments, the array substrate further includes: a plurality of first initialization signal lines, where the plurality of first initialization signal lines are located at a side of the plurality of pixel driving circuits away from the substrate, the plurality of first initialization signal line all extend along the row direction and are sequentially arranged along the column direction, and a first initialization signal line of the plurality of first initialization signal lines is electrically connected to first electrodes of first reset transistors of the row of pixel driving circuits. where in the row pixel region, the first initialization signal line is located at a side of the first reset signal line away from the first scanning signal line.

In some embodiments, the first reset transistor passes through the first reset signal line, an orthographic projection of a first electrode of the first reset transistor on the substrate is located between the orthographic projection of the first reset signal line on the substrate and an orthographic projection of the first initialization signal line on the substrate, and an orthographic projection of the second electrode of the first reset transistor on the substrate is located between the orthographic projection of the first reset signal line on the substrate and the orthographic projection of the second reset signal line on the substrate.

In some embodiments, the orthogonal projection of the first reset signal line on the substrate overlaps with the orthogonal projection of the second initialization signal line on the substrate.

In some embodiments, the array substrate further includes: a plurality of auxiliary signal lines, where the plurality of auxiliary signal lines are located at a side of the substrate, where the plurality of auxiliary signal lines all extend along the column direction and are sequentially arranged along the row direction. Herein, an auxiliary signal line is electrically connected to any one of the first initialization signal line, the second initialization signal line and the third initialization signal line.

In some embodiments, the row of pixel driving circuits is divided into a plurality of repeating units sequentially disposed along the row direction, where a repeating unit includes at least one of the pixel driving circuits. The auxiliary signal line is located between two adjacent repeating units in the row direction.

In some embodiments, the repeating unit includes two pixel driving circuits, and the two pixel driving circuits in the repeating unit are symmetrically disposed in the row direction.

In some embodiments, the plurality of auxiliary signal lines include a first auxiliary signal line, a second auxiliary signal line and a third auxiliary signal line, the first auxiliary signal line is electrically connected to the first initialization signal line, the second auxiliary signal line is electrically connected to the second initialization signal line, and the third auxiliary signal line is electrically connected to the third initialization signal line.

In some embodiments, the array substrate further includes: a light shielding layer, located between the substrate and the pixel driving circuit, where an orthographic projection of the light shielding layer on the substrate covers an orthographic projection of the driving transistor on the substrate.

In some embodiments, the light shielding layer includes a plurality of light shielding portions and a plurality of connection portions, where an orthographic projection of the light shielding portions on the substrate covers an orthographic projection of the driving transistor on the substrate. Herein, two adjacent light shielding portions in the row direction are connected via a connection portion; and/or, two adjacent light shielding portions in the column direction are connected via a connection portion; and the shading layer is configured to: receive a first voltage signal.

In another aspect, a display panel is provided. The display panel includes an array substrate as described in any of the above embodiments, a light-emitting device layer and an encapsulation layer. Herein, the light emitting device layer is located at a side of the array substrate away from the substrate; the encapsulation layer is located at a side of the light-emitting device layer away from the array substrate.

In yet another aspect, a display device is provided. The display device includes the display panel as described in any of the above embodiments and a driving chip.

### BRIEF DESCRIPTION OF THE DRAWINGS

In order to describe technical solutions in the present disclosure more clearly, drawings to be used in some embodiments of the present disclosure will be introduced briefly. Obviously, the drawings to be described below are merely drawings of some embodiments of the present disclosure, and a person of ordinary skill in the art may obtain other drawings according to those drawings. In addition, the drawings in the following description may be regarded as schematic diagrams, but are not limitations on actual sizes of products, actual processes of methods and actual timings of signals involved in the embodiments of the present disclosure.

FIG. 1 is a structural diagram of a display device in accordance with some embodiments.

FIG. 2 is a structural diagram of a display panel in accordance with some embodiments.

FIG. 3 is another structural diagram of a display panel in accordance with some embodiments.

FIG. 4 is yet another structural diagram of a display panel in accordance with some embodiments.

FIG. 5 is an equivalent circuit diagram of an “8T1C” pixel driving circuit in accordance with some embodiments.

FIG. 6 is a timing diagram of an “8T1C” pixel driving circuit in accordance with some embodiments.

FIG. 7 is a schematic diagram of an “8T1C” pixel driving circuit in a first stage t1 in accordance with some embodiments.

FIG. 8 is a schematic diagram of an “8T1C” pixel driving circuit in a second stage t2 in accordance with some embodiments.

FIG. 9 is a schematic diagram of an “8T1C” pixel driving circuit in a third stage t3 in accordance with some embodiments.

FIG. 10 is a schematic diagram of an “8T1C” pixel driving circuit in a fourth stage t4 in accordance with some embodiments.

FIG. 11 is a measured timing diagram of an “8T1C” pixel driving circuit.

FIG. 12 is a structural diagram of an array substrate in accordance with some embodiments.

FIG. 13 is a film layer structural diagram of an array substrate in accordance with some embodiments.

FIG. 14A is another film layer structural diagram of an array substrate in accordance with some embodiments.

FIG. 14B is yet another film layer structural diagram of an array substrate in accordance with some embodiments.

FIG. 15 is another structural diagram of an array substrate in accordance with some embodiments.

FIG. 16 is yet another structural diagram of an array substrate in accordance with some embodiments.

FIG. 17 is a structural diagram of a first active film layer of an array substrate in accordance with some embodiments.

FIG. 18A is another structural diagram of a first active film layer of an array substrate in accordance with some embodiments.

FIG. 18B is a film layer stacking diagram of an array substrate based on the first active film layer in FIG. 18A.

FIG. 19 is a structural diagram of a first gate metal layer of an array substrate in accordance with some embodiments.

FIG. 20 is a structural diagram of a stacked arrangement of a first active film layer and a first gate metal layer in accordance with some embodiments.

FIG. 21 is a structural diagram of a second gate metal layer of an array substrate in accordance with some embodiments.

FIG. 22 is a structural diagram of a stacked arrangement of a first active film layer, a first gate metal layer and a second gate metal layer in accordance with some embodiments.

FIG. 23 is a structural diagram of a second active film layer of an array substrate in accordance with some embodiments.

FIG. 24 is a structural diagram of a stacked arrangement of a first active film layer, a first gate metal layer, a second gate metal layer and a second active film layer in accordance with some embodiments.

FIG. 25 is a structural diagram of a third gate metal layer of an array substrate in accordance with some embodiments.

FIG. 26 is a structural diagram of a stacked arrangement of a first active film layer, a first gate metal layer, a second gate metal layer, a second active film layer and a third gate metal layer in accordance with some embodiments.

FIG. 27 is a structural diagram of an insulating layer of an array substrate in accordance with some embodiments.

FIG. 28 is a structural diagram of a stacked arrangement of a first active film layer, a first gate metal layer, a second gate metal layer, a second active film layer, a third gate metal layer and an insulating layer in accordance with some embodiments.

FIG. 29 is a structural diagram of a first source-drain metal layer of an array substrate in accordance with some embodiments.

FIG. 30 is a structural diagram of a stacked arrangement of a first active film layer, a first gate metal layer, a second gate metal layer, a second active film layer, a third gate metal layer, an insulating layer and a first source-drain metal layer in accordance with some embodiments.

FIG. 31 is a structural diagram of a second source-drain metal layer of an array substrate in accordance with some embodiments.

FIG. 32 is a structural diagram of a stacked arrangement of a first active film layer, a first gate metal layer, a second gate metal layer, a second active film layer, a third gate metal layer, an insulating layer, a first source-drain metal layer and a second source-drain metal layer in accordance with some embodiments.

### DESCRIPTION OF THE INVENTION

The technical solutions in some embodiments of the present disclosure will be described clearly and completely with reference to the drawings. Obviously, the described embodiments are merely some but not all embodiments of the present disclosure. All other embodiments obtained by a person having ordinary skill in the art based on the embodiments of the present disclosure shall be included in the protection scope of the present disclosure.

Unless the context requires otherwise, throughout the description and claims, the term “include” and other forms thereof such as the third-person singular form “includes” and the present participle form “including” are construed as an open and inclusive meaning, i.e., “including, but not limited to”. In the description of the specification, the terms such as “some embodiments”, “example”, or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials or characteristics may be included in any one or more embodiments or examples in any suitable manner.

Hereinafter, the terms such as “first” and “second” are used for descriptive purposes only, but are not to be construed as indicating or implying the relative importance or implicitly indicating a number of indicated technical features. Thus, a feature defined with “first” or “second” may explicitly or implicitly include one or more of this feature. In the description of the embodiments of the present disclosure, the terms “a plurality of”, “the plurality of” and “multiple” and other variations all mean two or more unless otherwise specified.

Some embodiments may be described by using the terms “couple”, “connect” and their derivatives. The term “connect” should be understood in a broad sense. For example, the term “connect” may represent a fixed connection, or a detachable connection, or being integrated; alternatively, the term “connect” may represent a direct connection, or an indirect connection through an intermediate medium. For example, the term “couple” indicates that two or more components are in direct physical contact or electrical contact. The term “couple” or “communicatively coupled” may also mean that two or more components are not in direct contact with each other, but still cooperate or interact with each other. The embodiments disclosed herein are not necessarily limited to the content herein.

“A and/or B” includes the following three combinations: only A, only B, and a combination of A and B.

The term such as “about” or “approximately” as used herein includes a stated value and an average value within an acceptable range of deviation of a particular value, where the acceptable range of deviation is determined by a person of ordinary skill in the art in consideration of measurement in question and errors associated with measurement of a particular quantity (i.e., a limitation of a measurement system).

The terms “parallel” and “perpendicular” as used herein include the stated conditions and conditions similar to the stated conditions, and the range of the similar conditions is within the acceptable range of deviation, where the acceptable range of deviation is determined by a person of ordinary skill in the art in consideration of the measurement in question and the error associated with the measurement of a particular quantity (i.e., a limitation of a measurement system). For example, the term “parallel” includes absolute parallelism and approximate parallelism, where an acceptable range of deviation of the approximate parallelism may be, for example, a deviation within 5⁰ the term “perpendicular” includes absolute perpendicularity and approximate perpendicularity, where an acceptable range of deviation of the approximate perpendicularity may also be, for example, a deviation within 5°.

It should be understood that when a layer or an element is referred to as being on another layer or substrate, the layer or element may be directly on the another layer or substrate, or there may be intermediate layer(s) between the layer or element and the another layer or substrate.

Exemplary implementations are described herein with reference to sectional views and/or plan views as idealized exemplary drawings. In the drawings, a thickness of layer and an area of region are enlarged for clarity. Therefore, variations in shape with respect to the drawings due to, for example, manufacturing technologies and/or tolerances may be envisaged. Therefore, the exemplary implementations should not be construed as being limited to the shapes of the regions shown herein, but including shape deviations due to, for example, manufacturing. For example, an etched region shown to have a rectangular shape generally has a feature being curved. Therefore, the regions shown in the drawings are schematic in nature, and shapes thereof are not intended to show actual shapes of the regions in a device, and are not intended to limit the scope of the exemplary implementations.

Some embodiments of the present disclosure provide a display device.

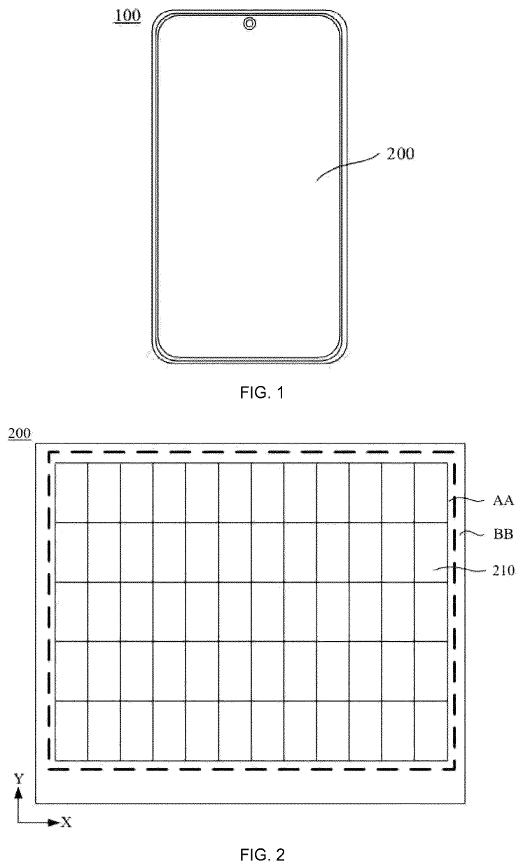

FIG. 1 is a structural diagram of a display device in accordance with some embodiments.

Please refer to FIG. 1, the display device 100 is a product having a function of displaying an image (including a static image or a dynamic image (which may be a video)). For example, the display device 100 may be any of: a display, a television, a billboard, a digital photo frame, a laser printer having a display function, a telephone, a mobile phone, a personal digital assistant (PDA), a digital camera, a portable camcorder, a view finder, a navigator, a vehicle, a large-area wall, a household appliance, an information inquiry device (e.g., a business inquiry device for a department of e-government, a bank, a hospital, an electric power or the like) and a monitor.

The display device 100 includes a display panel 200 and a driving chip, where the driving chip is electrically connected to the display panel 200 and may provide the display panel 200 with a data signal required for the display panel 200 to emit light.

FIG. 2 is a structural diagram of a display panel 200 in accordance with some embodiments.

Please refer to FIG. 2, the display panel 200 may include a display region AA and a peripheral region BB located at a side of the display region AA. Herein, the peripheral region BB surrounds the display region AA for a whole circle.

The display panel 200 may include a plurality of sub-pixels 210, and the plurality of sub-pixels 210 are disposed in the display region AA, where the plurality of sub-pixels may be arranged in an array.

The sub-pixels 210 are the smallest unit for the display panel 200 to display a picture, and the plurality of sub-pixels 210 may include a red sub-pixel, a blue sub-pixel and a green sub-pixel. By adjusting the luminance (gray scale) of sub-pixels with different colors, multi-color display may be realized through color combination and superposition, thus realizing a full-color display of the display panel 200.

In some other examples, the display panel 200 further includes a white sub-pixel.

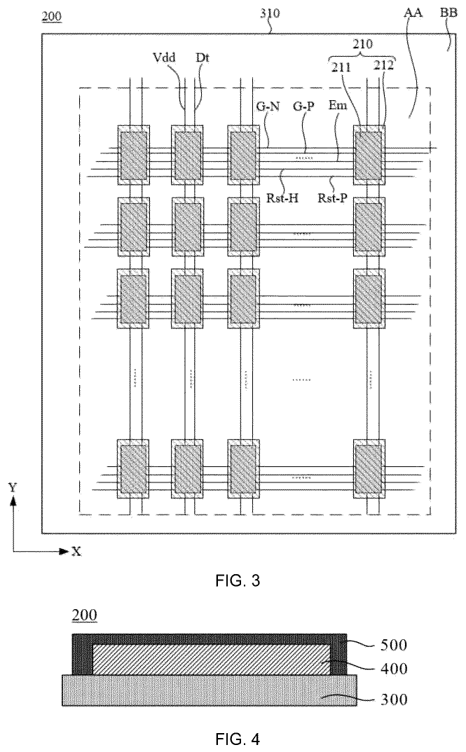

FIG. 3 is another structural diagram of a display panel 200 in accordance with some embodiments.

Please refer to FIG. 3, each sub-pixel 210 may include a light-emitting device 212 and a pixel driving circuit 211 for driving the light-emitting device 212 to emit light.

In addition, the display panel 200 further includes a plurality of signal lines. Exemplarily, the signal lines may include a data line Dt, a first power signal line Vdd, a first scanning signal line G-N, a second scanning signal line G-P, a light-emitting control signal line Em, a first reset signal line Rst-P, a second reset signal line Rst-H, a first initialization signal line (not shown in FIG. 3), a second initialization signal line, and a third initialization signal line, etc. The above-mentioned plurality of signal lines may be electrically connected to the pixel driving circuit 211, so as to provide a required signal for the pixel driving circuit 211.

FIG. 4 is yet another structural diagram of a display panel 200 in accordance with some embodiments.

Please refer to FIG. 4, the display panel 200 includes an array substrate 300, a light-emitting device layer 400 and an encapsulation layer 500 that are sequentially stacked.

Herein, the array substrate 300 includes a plurality of pixel driving circuits 211 (as shown in FIG. 3), and the light-emitting device layer 400 includes a plurality of light-emitting devices 212 (as shown in FIG. 3).

The light-emitting device layer 400 includes an anode, a light-emitting layer, and a cathode layer that are sequentially stacked. In some examples, an electron transport layer is further disposed between the cathode layer and the light-emitting layer, and a hole transport layer is further disposed between the anode layer and the light-emitting layer.

The encapsulation layer 500 may cover a plurality of light-emitting devices 212 in the light-emitting device layer 400 to clad the light emitting devices 212, so as to prevent water vapor and oxygen in the external environment from entering the display panel 200, thereby damaging the organic materials in the light-emitting devices 212 and shortening the service life of the display panel 200.

In some embodiments, the pixel driving circuit 211 includes a plurality of transistors. In some embodiments, a structure of the pixel driving circuit 211 in the present disclosure includes various types, which may be set according to actual needs. For example, a structure of the pixel driving circuit may include “2T1C”, “6T1C”, “7T1C”, “6T2C”, “7T2C” or “8T1C”, etc. Herein, “T” represents a thin film transistor, a number before “T” represents a number of thin film transistors; “C” represents a storage capacitor, and a number before “C” represents a number of storage capacitors. The following is an example of the pixel driving circuit of “8T1C” for introduction.

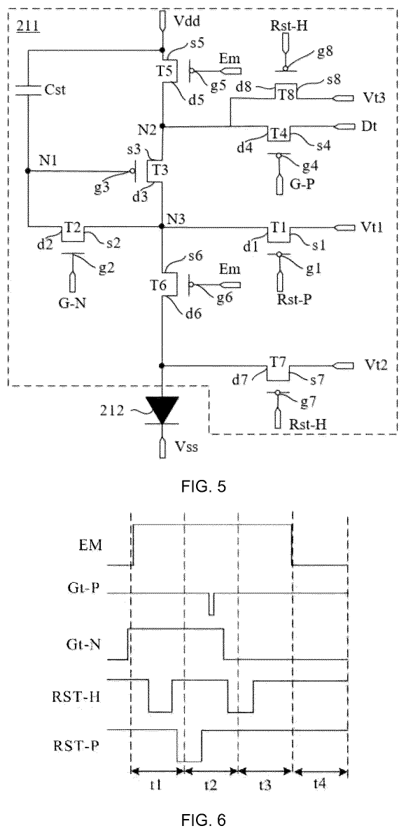

FIG. 5 is an equivalent circuit diagram of an “8T1C” pixel driving circuit 211 in accordance with some embodiments.

Please refer to FIG. 5, the pixel driving circuit 211 includes a first reset transistor T1, a compensation transistor T2, a driving transistor T3, a data writing transistor T4, a first light-emitting control transistor T5, a second light-emitting control transistor T6, a second reset transistor T7, a third reset transistor T8 and a capacitor Cst.

Herein, a gate g1 of the first reset transistor T1 is electrically connected to a first reset signal line Rst-P, a first electrode s1 of the first reset transistor T1 is electrically connected to a first initialization signal line Vt1, and the second electrode d1 of the first reset transistor t1 is electrically connected to a third node N3.

A gate g2 of the compensation transistor T2 is electrically connected to a first scanning signal line G-N, a first electrode s2 of the compensation transistor T2 is electrically connected to the third node N3, and a second electrode d2 of the compensation transistor T2 is electrically connected to a first node N1.

Agate g3 of the driving transistor T3 is electrically connected to the first node N1, a first electrode s3 of the driving transistor T3 is electrically connected to a second node N2, and a second electrode d3 of the driving transistor T3 is electrically connected to the third node N3.

A gate g4 of the data writing transistor T4 is electrically connected to a second scanning signal line G-P, a first electrode s4 of the data writing transistor T4 is electrically connected to a data signal line Dt, and a second electrode d4 of the data writing transistor T4 is electrically connected to the second node N2.

A gate g5 of the first light-emitting control transistor T5 is electrically connected to a light-emitting control signal line Em, a first electrode s5 of the first light-emitting control transistor T5 is electrically connected to a first power signal line Vdd, and a second electrode d5 of the first light-emitting control transistor T5 is electrically connected to the second node N2.

A gate g6 of the second light-emitting control transistor T6 is electrically connected to the light-emitting control signal line Em, a first electrode s6 of the second light-emitting control transistor T6 is electrically connected to the third node N3, and a second electrode d6 of the second light-emitting control transistor T6 is electrically connected to an anode of the light-emitting device 212.

A gate g7 of the second reset transistor T7 is electrically connected to the second reset signal line Rst-H, a first electrode s7 of the second reset transistor T7 is electrically connected to the second initialization signal line Vt2, and a second electrode d7 of the second reset transistor T7 is electrically connected to the anode of the light-emitting device 212 and the second electrode d6 of the second light-emitting control transistor T6.

A gate g8 of the third reset transistor T8 is electrically connected to the second reset signal line Rst-H, a first electrode s8 of the third reset transistor T8 is electrically connected to a third initialization signal line Vt3, and a second electrode d8 of the third reset transistor T8 is electrically connected to the second node N2 and a second electrode d4 of the data writing transistor T4.

A first electrode of the capacitor Cst is electrically connected to the first node N1, and a second electrode of the capacitor Cst is electrically connected to the first power signal line Vdd.

A cathode of the light-emitting device 212 is electrically connected to a second power signal line.

In some examples, a voltage of a power signal provided by the first power signal line Vdd is higher than a voltage of a power signal provided by the second power signal line.

In some examples, the compensation transistor T2 may be an N-type transistor, and the first reset transistor T1, the driving transistor T3, the data writing transistor T4, the first light-emitting control transistor T5, the second light-emitting control transistor T6, the second reset transistor T7 and the third reset transistor T8 may be P-type transistors.

In some examples, the compensation transistor T2 may be an oxide transistor, which may be an N-type transistor, and the other transistors may be LTPS (Low Temperature Poly Silicon) transistors, which may be P-type transistors.

Herein, the N-type transistor is turned on when a gate receives a high voltage signal, and the P-type transistor is turned on when a gate receives a low voltage signal. It should be noted that the “high voltage signal” and “low voltage signal” mentioned above are popular expressions. Generally speaking, the turn-on condition of an N-type transistor is that the gate-source voltage difference is greater than a threshold voltage thereof, that is, the gate voltage of an N-type transistor is greater than the sum of a source voltage and a threshold voltage thereof, and the threshold voltage of a N-type transistor is a positive value. In this case, the gate voltage signal that turns on the N-type transistor is called a high voltage signal. The turn-on condition of a P-type transistor is that the absolute value of the gate-source voltage difference is greater than a threshold voltage thereof, and the threshold voltage of a P-type transistor is a negative value, that is, the gate voltage of a P-type transistor is less than the sum of a source voltage and a threshold voltage thereof. In this case, the gate voltage signal that turns on the P-type transistor is called a low voltage signal. Herein, the voltage of the “high voltage signal” is greater than the voltage of the “low voltage signal”.

In some examples, the plurality of transistors mentioned above may all be P-type transistors, while in the remaining examples, the plurality of transistors mentioned above may all be N-type transistors.

In the following, taking the compensation transistor T2 as an N-type transistor and the other transistors as P-type transistors as an example, the driving process of the pixel driving circuit 211 provided by some embodiments of the present disclosure will be introduced.

FIG. 6 is a timing diagram of an “8T1C” pixel driving circuit 211 in accordance with some embodiments.

Please refer to FIG. 6, the first scanning signal line G-N is used to transmit the first scanning signal Gt-N, the second scanning signal line G-P is used to transmit the second scanning signal Gt-P, the light-emitting control signal line Em is used to transmit the light-emitting control signal EM, the first reset signal line Rst-P is used to transmit the first reset signal RST-P, and the second reset signal line Rst-H is used to transmit the second reset signal RST-H.

The driving process of the pixel driving circuit 211 is that a frame period includes a first stage t1, a second stage t2, a third stage t3 and a fourth stage t4.

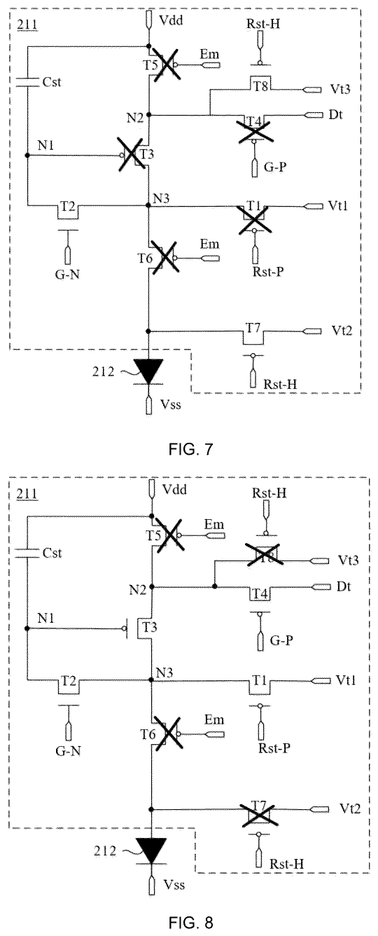

FIG. 7 is a schematic diagram of an “8T1C” pixel driving circuit 211 in a first stage t1 in accordance with some embodiments. Herein, it should be noted that in FIG. 7, the transistor covered with “x” indicates that the transistor is in a turned-off state, at this time, the first electrode of the transistor and the second electrode of the transistor are not opened, and the transistor not covered with “x” indicates that the transistor is in a turned-on state, at this time, the first electrode of the transistor and the second electrode of the transistor are conductive.

Please refer to FIG. 7 and in combination with FIG. 6 at the same time, the second reset signal RST-H is at a low level. Under the control of the second reset signal RST-H, the second reset transistor T7 and the third reset transistor T8 are turned on. Therefore, a second initialization signal provided by the second initialization signal line Vt2 may reset an anode of the light-emitting device 212 through the second reset transistor T7, and a third initialization signal provided by the third initialization signal line Vt3 may reset the second node N2 through the third reset transistor T8.

The light-emitting control signal EM is at a high level. Under the control of the light-emitting control signal EM, the first light-emitting control transistor T5 and the second light-emitting control transistor T6 are in a turned-off state.

The second scanning signal Gt-P is at a high level, and the data writing transistor T4 is in a turned-off state under the control of the second scanning signal Gt-P.

The first scanning signal Gt-N is at a high level, and the compensation transistor T2 is in a turned-on state under the control of the first scanning signal Gt-N.

The first reset signal RST-P is at a high level, and the first reset transistor T1 is in a turned-off state under the control of the first reset signal RST-P.

The driving transistor T3 is in a turned-off state.

FIG. 8 is a schematic diagram of an “8T1C” pixel driving circuit 211 in a second stage t2 in accordance with some embodiments.

Please refer to FIG. 8 and in combination with FIG. 6 at the same time, the second reset signal RST-H changes to a high level, and under the control of the second reset signal RST-H, the second reset transistor T7 and the third reset transistor T8 are turned off.

The first reset signal RST-P changes to a low level, and under the control of the first reset signal RST-P, the first reset transistor T1 is turned on. At this time, the first initialization signal provided by the first initialization signal line Vt1 may be written to the third node N3 through the first reset transistor T1, so that the third node N3 may be reset.

At the same time, the first scanning signal Gt-N is at a high level, and under the control of the first scanning signal Gt-N, the compensation transistor T2 is in a turned-on state. At this time, the first initialization signal provided by the first initialization signal line Vt1 may be written into the first node N1 through the first reset transistor T1 and the compensation transistor T2, so that the first node N1 may be reset. At this time, the first node N1 may cause the driving transistor T3 to turn on.

When the driving transistor T3 is turned on, the first initialization signal provided by the first initialization signal line Vt1 may be written to the second node N2 through the first reset transistor T1 and the driving transistor T3, so that the second node N2 is reset.

Afterwards, the first reset signal RST-P changes to a high level, so that the first reset transistor T1 is turned off, and the second scanning signal Gt-P changes to a low level, and the data writing transistor T4 is turned on under the control of the second scanning signal Gt-P. Therefore, the data signal provided by the data signal line Dt may be sequentially written to the first node N1 through the data writing transistor T4, the second node N2, the driving transistor T3, the third node N3 and the compensation transistor T2. At this time, the first node N1 written with the data signal may turn off the driving transistor T3.

The light-emitting control signal EM is at a high level. Under the control of the light-emitting control signal EM, the first light-emitting control transistor T5 and the second light-emitting control transistor T6 are in a turned-off state.

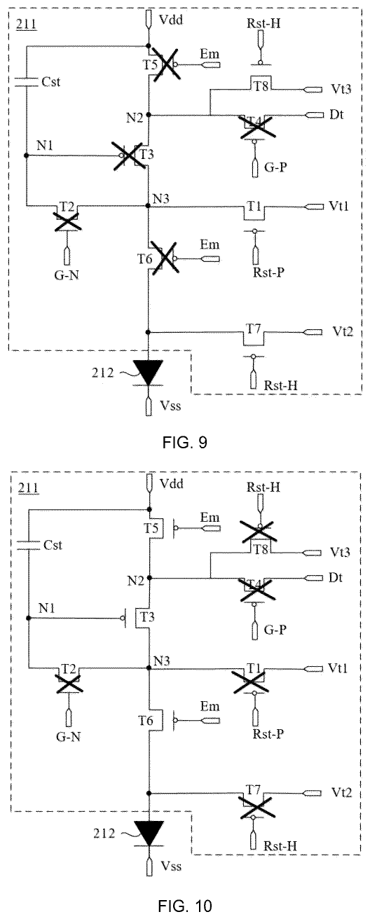

FIG. 9 is a schematic diagram of an “8T1C” pixel driving circuit 211 in a third stage t3 in accordance with some embodiments.

Please refer to FIG. 9 and in combination with FIG. 6 at the same time, the second scanning signal Gt-P changes to a high level, and the data writing transistor T4 is turned off under the control of the second scanning signal Gt-P.

The first scanning signal Gt-N changes to a low level, and under the control of the first scanning signal Gt-N, the compensation transistor T2 is turned off.

The second reset signal RST-H changes to a low level, and under the control of the second reset signal RST-H, the second reset transistor T7 and the third reset transistor T8 are turned on. Therefore, a second initialization signal provided by the second initialization signal line Vt2 may reset an anode of the light-emitting device 212 through the second reset transistor T7, and a third initialization signal provided by the third initialization signal line Vt3 may reset the second node N2 through the third reset transistor T8.

Afterwards, the second reset signal RST-H changes to a high level, so that the second reset transistor T7 and the third reset transistor T8 are turned off.

The first reset signal RST-P maintains a high level, and under the control of the first reset signal RST-P, the first reset transistor T1 is in a turned-off state.

The light-emitting control signal EM continues to maintain a high level, and under the control of the light-emitting control signal EM, the first light-emitting control transistor T5 and the second light-emitting control transistor T6 are in a turned-off state.

The driving transistor T3 is in a turned-off state.

FIG. 10 is a schematic diagram of an “8T1C” pixel driving circuit 211 in a fourth stage t4 in accordance with some embodiments.

Please refer to FIG. 10 and in combination with FIG. 6 at the same time, the light-emitting control signal EM changes to a low level. Under the control of the light-emitting control signal EM, the first light-emitting control transistor T5 and the second light-emitting control transistor T6 are turned on, and then a first power signal provided by the first power signal line Vdd may be written into the second node N2 through the first light-emitting control transistor T5. At this time, a voltage difference is formed between the second node N2 and the first node N1, so that the driving transistor T3 is turned on, and the second light-emitting control transistor T6 is turned on at the same time. Therefore, a first power signal provided by the first power signal line Vdd may be sequentially written into an anode of the light-emitting device 212 through the first light-emitting control transistor T5, the second node N2, the driving transistor T3, the third node N3 and the second light-emitting control transistor T6, so that the light-emitting device 212 emits light.

The second scanning signal Gt-P continues to maintain a high level, and under the control of the second scanning signal Gt-P, the data writing transistor T4 is turned off.

The first scanning signal Gt-N continues to maintain a low level, and under the control of the first scanning signal Gt-N, the compensation transistor T2 is turned off.

The second reset signal RST-H changes to a high level, and under the control of the second reset signal RST-H, the second reset transistor T7 and the third reset transistor T8 are turned off.

The first reset signal RST-P continues to maintain a high level, and under the control of the first reset signal RST-P, the first reset transistor T1 is in a turned-off state.

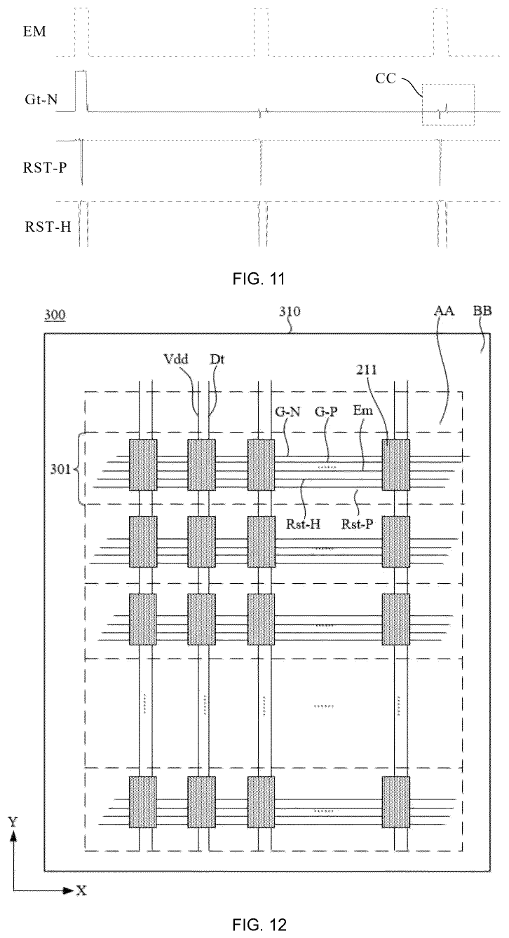

FIG. 11 is a measured timing diagram of an “8T1C” pixel driving circuit 211.

Please refer to FIG. 11, in the waveform test of the first scanning signal Gt-N of the actual product, the inventor found that at the moment when the transistor controlled by the second reset signal RST-H is turned on, the potential of the first scanning signal Gt-N will jump, and at this time, a spur will be generated in the waveform of the first scanning signal Gt-N. In FIG. 11, the spur in the waveform of the first scanning signal Gt-N is in the dotted box CC.

It is known from analysis that the potential jump of the first scanning signal Gt-N is mainly caused by an abrupt voltage transition of the second node N2 and the third node N3.

For example, please refer to FIG. 6 and FIG. 7 again. During the driving process of the above-mentioned pixel driving circuit 211, in the first stage t1, the second reset signal RST-H transmitted by the second reset signal line Rst-H is at a low level, so that the third reset transistor T8 controlled by the second reset signal RST-H may be turned on. At this time, the third initialization signal transmitted by the third initialization signal line Vt3 may be written to the second node N2 through the third reset transistor T8, so that the voltage of the second node N2 changes.

In the related art, the second node N2 overlaps with the first scanning signal line G-N, so a capacitance may be formed between the second node N2 and the first scanning signal line G-N. When the third initialization signal is written to the second node N2, the voltage of the second node N2 changes. Due to the capacitive coupling between the second node N2 and the first scanning signal line G-N, the voltage of the first scanning signal line G-N also changes with the voltage of the second node N2.

For another example, please refer to FIG. 6 and FIG. 8 again. In the second stage t2, the first reset signal RST-P changes to a low level, the first reset transistor T1 is turned on, and the first initialization signal provided by the first initialization signal line Vt1 may be written to the third node N3 through the first reset transistor T1, so that the third node N3 may be reset, thereby causing the voltage of the third node N3 to suddenly change. At the same time, the first scanning signal Gt-N is at a high level, and the compensation transistor T2 is in a turned-on state. At this time, the first initialization signal provided by the first initialization signal line Vt1 may be written into the first node N1 through the first reset transistor T1 and the compensation transistor T2, so that the first node N1 may be reset. At this time, the first node N1 may cause the driving transistor T3 to turn on. When the driving transistor T3 is turned on, the first initialization signal provided by the first initialization signal line Vt1 may be written to the second node N2 through the first reset transistor T1 and the driving transistor T3, thereby resetting the second node N2, so that the voltage of the second node N2 suddenly changes. In summary, in the second stage t2, the voltages of the second node N2 and the third node N3 may both suddenly change.

In the related art, the second node N2 and the third node N3 are both disposed to overlap with the first scanning signal line G-N. Therefore, the second node N2 and the third node N3 may form a capacitance with the first scanning signal line G-N.

Furthermore, when the voltages of the second node N2 and the third node N3 change, the voltage of the first scanning signal line G-N may change due to the capacitive coupling between the second node N2 and the first scanning signal line G-N, and the capacitive coupling between the third node N3 and the first scanning signal line G-N. In the related art, the capacitance between the second node N2 and the first scanning signal line G-N is 1.829 fF. The capacitance value between the third node N3 and the first scanning signal line G-N is 3.340 fF. At this time, the capacitance value between the second node N2 and the first scanning signal line G-N is large, and the capacitance value between the third node N3 and the first scanning signal line G-N is large.

In addition, in the related art, a first scanning signal line G-N may be disposed to overlap with the first nodes N1 of a row of pixel driving circuits 211, so that capacitances may be formed between the first scanning signal line G-N and the first nodes N1 of a row of pixel driving circuits 211. When the voltage change of the second node N2 and/or the third node N3 of a pixel driving circuit 211 causes the voltage of the first scanning signal line G-N electrically connected to the pixel driving circuit 211 to change, due to the capacitive coupling between the first scanning signal line G-N and the first node N1, the voltage of the first node N1 of the pixel driving circuit 211 will fluctuate, resulting in a voltage fluctuation of about 0.1 my at point N1.

At the same time, the first scanning signal line G-N will also affect the voltage of the first node N1 in the pixel driving circuit 211 adjacent to this pixel driving circuit 211 in the row direction. And the voltage of the first node N1 will affect the turn-on degree of the driving transistor T3, and further affect the luminance of the light-emitting device 212. This phenomenon may be called lateral crosstalk deterioration.

Based on this, the present disclosure provides an array substrate 300.

FIG. 12 is a structural diagram of an array substrate 300 in accordance with some embodiments.

Please refer to FIG. 12, the array substrate 300 includes: a substrate 310, a plurality of first scanning signal lines Gate-N (also referred to as first scanning signal lines G-N) and a plurality of pixel driving circuits 211. Herein, the plurality of pixel driving circuits 211 and the plurality of first scanning signal lines G-N are located at a side of the substrate 310.

The substrate 310 may include a display region AA and a peripheral region BB, where the display region AA of the substrate 310 is the same region as the display region AA of the display panel 200 provided in some of the above embodiments, and the peripheral region BB of the substrate 310 is the same region as the peripheral region BB of the display panel 200 provided in some of the above embodiments. And a plurality of row pixel regions 301 may be located in the display region AA.

The substrate 310 may be a single-layer structure or a stacked-layer structure; the substrate 310 may be rigid or flexible.

In addition to the substrate 310, the array substrate 300 may further include a first active layer, a first gate metal layer, a second gate metal layer, a second active layer, a third gate metal layer, a first source-drain metal layer and a second source-drain metal layer sequentially stacked on the substrate 310. For example, the first active layer and the first gate metal layer are used to form a part of transistors in the pixel driving circuit 211, such as a first reset transistor T1, a driving transistor T3, a data writing transistor T4, a first light-emitting control transistor T5, a second light-emitting control transistor T6, a second reset transistor T7 and a third reset transistor T8. And the second gate metal layer, the second active layer and the third gate metal layer may be used to form another part of transistors in the pixel driving circuit 211, such as, the compensation transistor T2. In addition, the first gate metal layer, the second gate metal layer and the third gate metal layer may also be used to form a part of signal lines that provide signal(s) to the pixel driving circuit 211. And the first source-drain metal layer and the second source-drain metal layer may be used to form the remaining signal lines that provide signal(s) to the pixel driving circuit 211.

For example, the plurality of first scanning signal lines G-N may be located at a side of the plurality of pixel driving circuits 211 away from the substrate 310. Herein, the plurality of pixel driving circuits 211 are arranged in multiple rows and multiple columns. A row of pixel driving circuits 211 extend along a row direction X, and a column of pixel driving circuits 211 extend along a column direction Y, where the row direction X and the column direction Y are both parallel to the substrate 310 and are cross-disposed.

In some examples, the row direction X and the column direction Y may be approximately vertically disposed. In this case, an angle between the row direction X and the column direction Y is approximately equal to 90. For example, the included angle between the row direction X and the column direction Y is 85°, 90°, or 95°.

The plurality of first scanning signal lines G-N all extend along the row direction X and are sequentially arranged along the column direction Y. For example, a first scanning signal line G-N passes through a row of pixel driving circuits 211. Herein, “passing through” may be understood as an orthographic projection of the first scanning signal line G-N on the substrate 310 overlaps with an orthographic projection of the pixel driving circuit 211 on the substrate 310.

Herein, the array substrate 300 may include: a plurality of row pixel regions 301, the plurality of row pixel regions 301 extend along the row direction X and are sequentially disposed along the column direction Y; a row of pixel driving circuits 211 are disposed in a row pixel region 301, and the first scanning signal line G-N, the second scanning signal line G-P, the light-emitting control signal line Em, the first reset signal line Rst-P and the second reset signal line Rst-H electrically connected to the row of pixel driving circuits 211 are all located in the row pixel region 301 where the row of pixel driving circuits 211 are located.

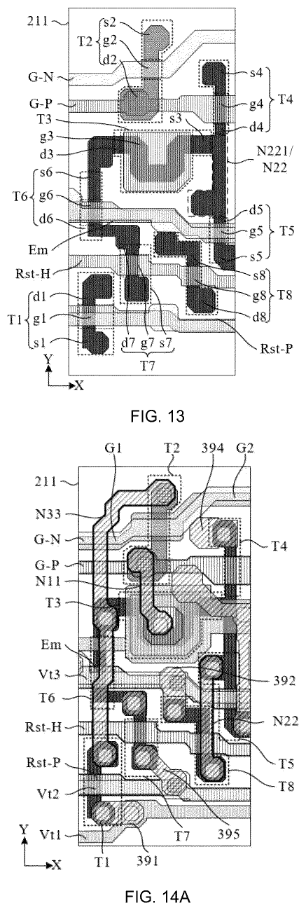

FIG. 13 is a film layer structural diagram of an array substrate 300 in accordance with some embodiments.

Please refer to FIG. 13, a pixel driving circuit 211 includes a compensation transistor T2 and a driving transistor T3. Herein, the compensation transistor T2 includes a control electrode g2, a first electrode s2 and a second electrode d2, and the driving transistor T3 includes a control electrode g3, a first electrode s3 and a second electrode d3.

A first scanning signal line G-N is electrically connected to control electrodes g2 of compensation transistors T2 of a row of pixel driving circuits 211, so that a first scanning signal line G-N may provide a first scanning signal Gt-N for the control electrodes g2 of the compensation transistors T2 in the row of pixel driving circuits 211.

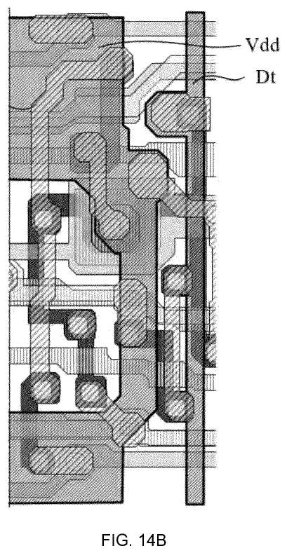

FIG. 14A is another film layer structural diagram of an array substrate 300 in accordance with some embodiments.

Please refer to FIG. 14A, a pixel driving circuit 211 further includes a first conductive connection portion N11, where the control electrode g3 of the driving transistor T3 (as shown in FIG. 13) and the second electrode d2 of the compensation transistor T2 (as shown in FIG. 13) are both electrically connected to the first conductive connection portion N11. The first conductive connection portion N11 does not overlap with the first scanning signal line G-N in a direction perpendicular to the substrate 310.

Herein, the first conductive connection portion N11 may be a first node N1 in the equivalent circuit diagram of the pixel driving circuit 211 (as shown in FIG. 5).

Herein, the first conductive connection portion N11 and the first scanning signal line G-N not overlapping in the direction perpendicular to the substrate 310 may be understood that an orthographic projection of the first conductive connection portion N11 on the substrate 310 and an orthographic projection of the first scanning signal line G-N on the substrate 310 do not overlap. Therefore, the capacitance between the first conductive connection portion N11 and the first scanning signal line G-N may be reduced.

As can be seen from the above, during the driving process of the pixel driving circuit 211, in the first stage t1, the third initialization signal transmitted by the third initialization signal line Vt3 may be written to the second node N2 through the third reset transistor T8, thereby causing the voltage of the second node N2 to suddenly change. In the second stage t2, the first initialization signal provided by the first initialization signal line Vt1 may be written to the third node N3 through the first reset transistor T1, thereby causing the voltage of the third node N3 to suddenly change. Thereafter, when the driving transistor T3 is turned on, the first initialization signal provided by the first initialization signal line Vt1 may be written to the second node N2 through the first reset transistor T1 and the driving transistor T3, thereby causing the voltage of the second node N2 to suddenly change. Herein, when the voltage of the second node N2 suddenly changes and/or the voltage of the third node N3 suddenly changes, the voltage of the first scanning signal line G-N will change. And in some embodiments of the present disclosure, by making the first conductive connection portion N11 not overlap with the first scanning signal line G-N, the capacitance value between the first conductive connection portion N11 and the first scanning signal line G-N may be reduced. Furthermore, when the voltage of the first scanning signal line G-N changes, the voltage change value of the first conductive connection portion N11 may be reduced, and the influence of the first scanning signal line G-N on the voltage of the first conductive connection portion N11 in the pixel driving circuit 211 adjacent to the above-mentioned pixel driving circuit 211 in the row direction X is reduced. In this way, the light-emitting luminance of the light-emitting device 212 driven by the adjacent pixel driving circuit 211 is less affected, so that the problem of lateral crosstalk may be improved. When the above-mentioned array substrate 300 is applied to the display panel 200, the display effect of the display panel 200 may be improved.

Please continue to refer to FIG. 14A, in some embodiments, the pixel driving circuit 211 further includes: a data writing transistor T4 and a first light-emitting control transistor T5. The second electrode d4 (as shown in FIG. 13) of the data writing transistor T4 is electrically connected to the first electrode s3 of the driving transistor T3 and the second electrode d5 (as shown in FIG. 13) of the first light-emitting control transistor T5.

The array substrate 300 further includes: a plurality of second scanning signal lines G-P and a plurality of light-emitting control signal lines Em, where the plurality of second scanning signal lines G-P and the plurality of light-emitting control signal lines Em are located at a side of the substrate 310. For example, the plurality of second scanning signal lines G-P and the plurality of light-emitting control signal lines Em may all be located at a side of the plurality of pixel driving circuits 211 away from the substrate 310.

Herein, a plurality of second scanning signal lines G-P all extend along the row direction X and are sequentially arranged along the column direction Y. A second scanning signal line G-P is electrically connected to control electrodes g4 (as shown in FIG. 13) of data writing transistors T4 of a row of pixel driving circuits 211. In this way, a second scanning signal line G-P may provide a second scanning signal Gt-P for the control electrodes g4 of the data writing transistors T4 of the row of pixel driving circuits 211.

The plurality of light-emitting control signal line Em all extend along the row direction X and are sequentially arranged along the column direction Y. A light-emitting control signal line Em is electrically connected to control electrodes g5 of first light-emitting control transistors T5 of a row of pixel driving circuits 211. In this way, a light-emitting control signal line Em may provide a light-emitting control signal EM for the first light-emitting control transistors T5 of the row of pixel driving circuits 211.

The first scanning signal line G-N, the second scanning signal line G-P and the light-emitting control signal line Em electrically connected to the row of pixel driving circuits 211 are all located in the row pixel region 301 (as shown in FIG. 12) where the row of pixel driving circuits 211 are located.

In the row pixel region 301 (as shown in FIG. 12): an orthographic projection of the first scanning signal line G-N on the substrate 310 is located at a side of an orthographic projection of the second scanning signal line G-P on the substrate 310 away from an orthographic projection of the light-emitting control signal line Em on the substrate 310, and an orthographic projection of the driving transistor T3 on the substrate 310 is located between the orthographic projection of the second scanning signal line G-P on the substrate 310 and the orthographic projection of the light-emitting control signal line Em on the substrate 310.

Please refer to FIG. 13 again, in the pixel driving circuit 211, a first electrode and a second electrode of a transistor are respectively located on both sides of a control electrode, and the gate line is electrically connected to the control electrode of the transistor. Therefore, a position of the gate line to which the transistor is electrically connected may determine a position of the transistor in the pixel driving circuit 211. Herein, the above transistors may include a first reset transistor T1, a compensation transistor T2, . . . , and a third reset transistor T8. And the gate line may include a first scanning signal line G-N, a second scanning signal line G-P, a light-emitting control signal line Em, a first reset signal line Rst-P and a second reset signal line Rst-H.

Herein, in the row pixel region 301 (as shown in FIG. 12): an orthographic projection of the first scanning signal line G-N on the substrate 310 is located at a side of an orthographic projection of the second scanning signal line G-P on the substrate 310 away from an orthographic projection of the light-emitting control signal line Em on the substrate 310, and an orthographic projection of the driving transistor T3 on the substrate 310 is located between the orthographic projection of the second scanning signal line G-P on the substrate 310 and the orthographic projection of the light-emitting control signal line Em on the substrate 310. Herein, the first conductive connection portion N11 is electrically connected to the control electrode g3 of the driving transistor T3 and the second electrode d2 of the compensation transistor T2. Therefore, an orthographic projection of an end of the first conductive connection portion N11 electrically connected to the driving transistor T3 on the substrate 310 is located at a side of the second scanning signal line G-P away from an orthographic projection of the first scanning signal line G-N on the substrate 310. In addition, the first conductive connection portion N11 does not overlap with the first scanning signal line G-N.

Therefore, the orthographic projection of the first conductive connection portion N11 on the substrate 310 may be located at a side of the orthographic projection of the second scanning signal line G-P on the substrate 310 away from the orthographic projection on the substrate 310, so that the first conductive connection portion N11 does not overlap with the first scanning signal line G-N.

Please continue to refer to FIG. 14A, in some embodiments, in a row pixel region 301 (as shown in FIG. 12), the compensation transistors T2 and the first conductive connection portions N11 are sequentially disposed along the column direction Y. Herein, the compensation transistors T2 pass through the first scanning signal line G-N.

Herein, the first electrode s2 and the second electrode d2 of the compensation transistor T2 are respectively located on both sides of the first scanning signal line G-N in the column direction Y.

The orthographic projection of the first electrode s2 of the compensation transistor T2 on the substrate 310 is located at a side of the orthographic projection of the first scanning signal line G-N on the substrate 310 away from the orthographic projection of the light-emitting control signal line Em on the substrate 310.

An orthographic projection of the second electrode d2 of the compensation transistor T2 on the substrate 310 is located at a side of an orthographic projection of the first scanning signal line G-N on the substrate 310 close to an orthographic projection of the light-emitting control signal line Em on the substrate 310, and the first conductive connection portion N11 is located at a side of the first scanning signal line G-N close to the light-emitting control signal line Em.

Herein, “the compensation transistors T2 pass through the first scanning signal line G-N” may be understood as: an orthographic projection of the compensation transistor T2 on the substrate 310 overlaps with an orthographic projection of the first scanning signal line G-N on the substrate 310. Herein, the overlapping portion of the first scanning signal line G-N and the compensation transistor T2 may be reused as the control electrode g2 of the compensation transistor T2.

Herein, the first conductive connection portion N11 is electrically connected to the second electrode d2 of the compensation transistor T2. Therefore, an orthographic projection of the first conductive connection portion N11 on the substrate 310 overlaps with an orthographic projection of the second electrode d2 of the compensation transistor T2 on the substrate 310.

An end of the first conductive connection portion N11 is electrically connected between the control electrode g3 of the driving transistor T3 (as shown in FIG. 13) and the second electrode d2 of the compensation transistor T2 (as shown in FIG. 13), where an orthographic projection of the second electrode d2 of the compensation transistor T2 on the substrate 310 is located at a side of an orthographic projection of the first scanning signal line G-N on the substrate 310 close to an orthographic projection of the light-emitting control signal line Em on the substrate 310. Therefore, an orthographic projection of an end of the first conductive connection portion N11 electrically connected to the second electrode d2 of the compensation transistor T2 on the substrate 310 may be located at a side of an orthographic projection of the first scanning signal line G-N on the substrate 310 close to an orthographic projection of the light-emitting control signal line Em on the substrate 310. It can be seen from some of the above embodiments that the orthographic projection of an end of the first conductive connection portion N11 electrically connected to the driving transistor T3 on the substrate 310 is located at a side of the second scanning signal line G-P away from an orthographic projection of the first scanning signal line G-N on the substrate 310. Therefore, an orthographic projection of the first conductive connection portion N11 as a whole on the substrate 310 is located at a side of an orthographic projection of the first scanning signal line G-N on the substrate 310 close to an orthographic projection of the light-emitting control signal line Em on the substrate 310, so that the first conductive connection portion N11 and the first scanning signal line G-N do not overlap.

Please continue to refer to FIG. 14A, in the row pixel region 301 (as shown in FIG. 12): a portion of an orthographic projection of the data writing transistor T4 on the substrate 310 is disposed opposite to an orthographic projection of the compensation transistor T2 on the substrate 310 in the row direction X, and another portion of the orthographic projection of the data writing transistor T4 on the substrate 310 is disposed opposite to the orthographic projection of the first conductive connection portion N11 on the substrate 310 in the row direction X. With such configuration, the size of the pixel driving circuit 211 in the column direction Y may be reduced.

Herein, the data writing transistor T4 is located at a side of the compensation transistor T2 in the row direction X, and the data writing transistor T4 is also located at a side of the first conductive connection portion N11 in the row direction X.

Please continue to refer to FIG. 14A, a data writing transistor T4 passes through the second scanning signal line G-P, and the data writing transistor T4 is located at a side of the first scanning signal line G-N close to the light-emitting control signal line Em. Herein, a second scanning signal line G-P overlaps with data writing transistors T4 in a row of pixel driving circuits 211.

The array substrate 300 further includes: a plurality of data transfer portions 394, and the plurality of data transfer portions 394 are located at a side of the plurality of pixel driving circuits 211 away from the substrate 310.

FIG. 14B is yet another film layer structural diagram of an array substrate 300 in accordance with some embodiments.

Please refer to FIG. 14B, and in combination with FIG. 14A, the array substrate 300 further includes: a plurality of data lines Dt. The plurality of data lines Dt are located at a side of the data transfer portions 394 away from the substrate 310. The plurality of data lines Dt all extend along the column direction Y and are sequentially arranged along the row direction Y. A data line Dt is electrically connected to first electrodes s4 of data writing transistors T4 of a row of pixel driving circuits 211 through a data transfer portion 394.

Herein, in the row pixel region 301, an orthographic projection of the data transfer portion 394 on the substrate 310 is located between an orthographic projection of the first scanning signal line G-N on the substrate 310 and an orthographic projection of the second scanning signal line G-P on the substrate 310.

Herein, the data line Dt may be electrically connected to the first electrode s4 of the data writing transistor T4 through the data transfer portion 394. Therefore, the data transfer portion 394 may receive a data signal transmitted by the data line Dt, and thus, the voltage of the data transfer portion 394 may change with the data signal. When the voltage of the data transfer portion 394 changes, it may interfere with a transistor around the data transfer portion 394. By setting the data transfer portion 394 between the first scanning signal line G-N and the second scanning signal line G-P, the first scanning signal line G-N and the second scanning signal line G-P may shield the interference caused by the data transfer portion 394 to other transistors.

In some examples, there are at least two different intervals between the first scanning signal line G-N and the second scanning signal line G-P in the column direction Y. For example, the first scanning signal line G-N may include a main body portion G1 and an isolation portion G2, where an orthographic projection of the main body portion G1 on the substrate 310 may be disposed opposite to an orthographic projection of the data writing transistor T4 on the substrate 310 in the column direction Y, and an orthographic projection of the isolation portion G2 on the substrate 310 may be disposed opposite to the orthographic projection of the data transfer portion 394 on the substrate 310 in the column direction Y. Herein, a distance between the isolation portion G2 and the second scanning signal line G-P in the column direction Y is greater than a distance between the main body portion G1 and the second scanning signal line G-P in the column direction Y. With such configuration, a large space may be provided for the arrangement of the data transfer portion 394.

In some examples, there are at least two different intervals between the isolation portion G2 and the second scanning signal line G-P in the column direction Y. For example, the isolation portion G2 may include a first isolation portion connected to the main body portion G1 and a second isolation portion connected to the first isolation portion, where a distance between the second isolation portion and the second scanning signal line G-P in the column direction Y is greater than a distance between the first isolation portion and the second scanning signal line G-P in the column direction Y. Herein, the first isolation portion may extend in a direction away from the second scanning signal line G-P.

Please continue to refer to FIG. 14A, in a row pixel region 301 (as shown in FIG. 12), a portion of an orthographic projection of the first conductive connection portion N11 on the substrate 310 overlaps a portion of an orthographic projection of the compensation transistor T2 on the substrate 310. For example, a portion of an orthographic projection of the first conductive connection portion N11 on the substrate 310 mentioned above may overlap with an orthographic projection of the second electrode d2 of the compensation transistor T2 on the substrate 310.

Another portion of the orthographic projection of the first conductive connection portion N11 on the substrate 310 overlaps with a portion of an orthographic projection of the driving transistor T3 on the substrate 310.

Herein, an orthographic projection of the second electrode d2 of the compensation transistor T2 on the substrate 310 and an orthographic projection of the driving transistor T3 on the substrate 310 are both located at a side of the first scanning signal line G-N close to the light-emitting control signal line Em. At this time, the second scanning signal line G-P, the light-emitting control signal line Em, the second electrode d2 of the compensation transistor T2 and the driving transistor T3 are located on the same side of the first scanning signal line G-N in the column direction Y. With such configuration, an orthographic projection of the first conductive connection portion N11 on the substrate 310 and an orthographic projection of the first scanning signal line G-N on the substrate 310 do not overlap.

Please continue to refer to FIG. 14A, in some embodiments, the pixel driving circuit 211 further includes a second conductive connection portion N22, which is electrically connected to the first electrode s3 of the driving transistor T3, the second electrode d5 of the first light-emitting control transistor T5, and the second electrode d4 of the data writing transistor T4.

An orthographic projection of the second conductive connection portion N22 on the substrate 310 does not overlap with an orthographic projection of the first scanning signal line G-N on the substrate 310.

Herein, the second conductive connection portion N22 may be a second node N2 in the equivalent circuit diagram of the pixel driving circuit 211 (as shown in FIG. 5).

Herein, the orthographic projection of the second conductive connection portion N22 on the substrate 310 not overlapping with the orthographic projection of the first scanning signal line G-N on the substrate 310 may be understood that the second conductive connection portion N22 and the first scanning signal line G-N do not overlap in a direction perpendicular to the substrate 310, thereby reducing the capacitance between the second conductive connection portion N22 and the first scanning signal line G-N.

Please refer to FIG. 14A again, and in combination with FIG. 7 and FIG. 8, during the driving process of the pixel driving circuit 211, in both the first stage t1 and the second stage t2, the voltage of the second conductive connection portion N22 will suddenly change. By making the orthogonal projection of the second conductive connection portion N22 and the orthogonal projection of the first scanning signal line G-N perpendicular to the substrate 310 not overlap, the capacitance formed between the second conductive connection portion N22 and the first scanning signal line G-N may be reduced, thereby reducing the influence of the voltage mutation of the second conductive connection portion N22 on the voltage of the first scanning signal line G-N, reducing the voltage change value of the first scanning signal line G-N, and further reducing the influence of the first scanning signal line G-N on the voltage of the first conductive connection portion N11, that is, reducing the voltage change value of the first conductive connection portion N11. In summary, in some embodiments of the present disclosure, by making the orthogonal projection of the second conductive connection portion N22 and the orthogonal projection of the first scanning signal line G-N perpendicular to the substrate 310 do not overlap, the voltage change of the first scanning signal line G-N may further have less effect on the light-emitting luminance of the light-emitting device 212. In addition, when the voltage change value of the first scanning signal line G-N is small, the first scanning signal line G-N has a small effect on the voltage of the first conductive connection portion N11 in the pixel driving circuit 211 adjacent to the above-mentioned pixel driving circuit 211 in the row direction X, thereby having a small effect on the light-emitting luminance of the light-emitting device 212 driven by the adjacent pixel driving circuit 211, and thus, improving the problem of lateral crosstalk. When the above-mentioned array substrate 300 is applied to the display panel 200, the display effect of the display panel 200 may be improved.

Herein, the second scanning signal line G-P is electrically connected to the control electrode g4 of the data writing transistor T4, and the light control signal line Em is electrically connected to the control electrode g5 of the first light-emitting control transistor T5. Therefore, a position of the second scanning signal line G-P may determine a position of the control electrode g4 of the data writing transistor T4, and a position of the light control signal line Em may determine a position of the control electrode g5 of the first light-emitting control transistor T5.

In some of the above embodiments, in a row pixel region 301 (as shown in FIG. 12): an orthographic projection of the first scanning signal line G-N on the substrate 310 is located at a side of an orthographic projection of the second scanning signal line G-P on the substrate 310 away from an orthographic projection of the light-emitting control signal line Em on the substrate 310, and the driving transistor T3 is located between the second scanning signal line G-P and the light-emitting control signal line Em. With such configuration, the driving transistor T3, the data writing transistor T4 and the first light-emitting control transistor T5 are located on the same side of the first scanning signal line G-N.

Herein, the second conductive connection portion N22 is electrically connected to the second electrode d4 of the data writing transistor T4, the second electrode d5 of the first light-emitting control transistor T5 and the control electrode g3 of the driving transistor T3. Therefore, the second conductive connection portion N22 may be located on the same side of the first scanning signal line G-N as the data writing transistor T4, the first light-emitting control transistor T5 and the driving transistor T3, so that the second conductive connection portion N22 and the first scanning signal line G-N do not overlap, thereby reducing the capacitance value of the capacitance formed between the second conductive connection portion N22 and the first scanning signal line G-N.

In some embodiments, the data writing transistor T4 and the first light-emitting control transistor T5 are sequentially disposed along the column direction Y, and the first light-emitting control transistor T5 is located at a side of the data writing transistor T4 away from the first scanning signal line G-N.

In some embodiments, the pixel driving circuit 211 further includes: a third reset transistor T8, where a second electrode d8 of the third reset transistor T8 is electrically connected to the second conductive connection portion N22.

The array substrate 300 further includes: a plurality of second reset signal lines Rst-H, where the plurality of second reset signal lines Rst-H are located at a side of the plurality of pixel driving circuits 211 away from the substrate 310, and the plurality of second reset signal lines Rst-H all extend along the row direction X and are sequentially arranged along the column direction Y.

A second reset signal line Rst-H is electrically connected to control electrodes g8 of third reset transistors T8 of a row of pixel driving circuits 211, and thus a second reset signal line Rst-H may provide a second reset signal RST-H for the control electrodes g8 of the third reset transistors T8 of the row of pixel driving circuits 211.

The second reset signal line Rst-H to which the row of pixel driving circuits 211 are electrically connected is located in a row pixel region 301 (as shown in FIG. 12) where the row of pixel driving circuits 211 are located.

Herein, in a row pixel region (as shown in FIG. 12): the second reset signal line Rst-H is located at a side of the light-emitting control signal line Em away from the first scanning signal line G-N.

By making the second reset signal line Rst-H at a side of the light-emitting control signal line Em away from the first scanning signal line G-N, the third reset transistor T8 and the first light-emitting control transistor T5 may be located at the same side of the first scanning signal line G-N. From some of the above embodiments, it can be seen that the data writing transistor T4, the driving transistor T3, and the first light-emitting control transistor T5 may be located at the same side of the first scanning signal line G-N. And the second conductive connection portion N22 may be electrically connected to the second electrode d8 of the third reset transistor T8, the second electrode d4 of the data writing transistor T4, the first electrode s3 of the driving transistor T3, and the second electrode d5 of the first light-emitting control transistor T5.

Since the third reset transistor T8, the data writing transistor T4, the driving transistor T3 and the first light-emitting control transistor T5 are all located at the same side of the first scanning signal line G-N, so that the second conductive connection portion N22 can be avoided from overlapping with the first scanning signal line G-N, thereby reducing the capacitance value between the second conductive connection portion N22 and the first scanning signal line G-N.

In some embodiments, the array substrate 300 further includes: a plurality of third initialization signal lines Vt3 located at a side of the substrate 310. For example, the plurality of third initialization signal lines Vt3 may be located at a side of the plurality of pixel driving circuits 211 facing away from the substrate 310.

The plurality of third initialization signal lines Vt3 all extend along the row direction X and are sequentially arranged along the column direction Y, and a third initialization signal line Vt3 is electrically connected to a first electrode s3 of a third reset transistor T8 of a row of pixel driving circuits 211.

The third initialization signal line Vt3 electrically connected to the row of pixel driving circuits 211 is located in a row pixel region 301 (as shown in FIG. 12) where the row of pixel driving circuits 211 are located.

Herein, in the row pixel region 301 (as shown in FIG. 12): an orthographic projection of the third initialization signal line Vt3 on the substrate 310 at least partially overlaps with an orthographic projection of the light-emitting control signal line Em on the substrate 310. At this time, the orthographic projection of the third initialization signal line Vt3 on the substrate 310 is located between the orthographic projection of the second reset signal line Rst-H on the substrate 310 and the orthographic projection of the second scanning signal line G-P on the substrate 310.

Herein, the orthographic projection of the third initialization signal line Vt3 on the substrate 310 at least partially overlaps with the orthographic projection of the light-emitting control signal line Em on the substrate 310, so that the size of the pixel driving circuit 211 in the column direction Y may be reduced.

Please continue to refer to FIG. 14A and in combination with FIG. 13, in a row pixel region 301 (as shown in FIG. 12): a third reset transistor T8 passes through the second reset signal line Rst-H and is located at a side of the third initialization signal line Vt3 away from the light-emitting control signal line Em.

Herein, the first electrode s8 and the second electrode d8 of the third reset transistor T8 are located at both sides of the second reset signal line Rst-H in the column direction Y, respectively. For example, the orthographic projection of the first electrode s8 of the third reset transistor T8 on the substrate 310 is located between the orthographic projection of the third initialization signal line Vt3 on the substrate 310 and the orthographic projection of the second reset signal line Rst-H on the substrate 310, so the first electrode s8 of the third reset transistor T8 is disposed adjacent to the third initialization signal line Vt3 in the column direction Y.

The orthographic projection of the second electrode d8 of the third reset transistor T8 on the substrate 310 is located at a side of the orthographic projection of the second reset signal line Rst-H on the substrate 310 away from the orthographic projection of the third initialization signal line Vt3 on the substrate 310.

Herein, the first electrode s8 of the third reset transistor T8 is electrically connected to the third initialization signal line Vt3, and the first electrode s8 of the third reset transistor T8 and the third initialization signal line Vt3 are adjacently disposed in the column direction Y, so that the first electrode s8 of the third reset transistor T8 and the third initialization signal line Vt3 may be electrically connected.

In some examples, the array substrate 300 may further include a second transfer portion 392, where the second transfer portion 392 may be electrically connected to the third initialization signal line Vt3 and the first electrode s8 of the third reset transistor T8, respectively. For example, two ends of the orthographic projection of the second transfer portion 392 on the substrate 310 may overlap with the orthographic projection of the third initialization signal line Vt3 on the substrate 310 and the orthographic projection of the first electrode s8 of the third reset transistor T8 on the substrate 310, respectively.

The second conductive connection portion N22 crosses over the third initialization signal line Vt3, the light-emitting control signal line Em, and the second reset signal line Rst-H, and is electrically connected to the second electrode d8 of the third reset transistor T8.

Herein, the second conductive connection portion N22 crossing over the third initialization signal line Vt3, the light-emitting control signal line Em and the second reset signal line Rst-H may be understood that the orthographic projection of the second conductive connection portion N22 on the substrate 310 may partially overlap with the orthographic projection of the third initialization signal line Vt3, the light-emitting control signal line Em and the second reset signal line Rst-H on the substrate 310.

For example, the second conductive connection portion N22 extends along the column direction Y.

In some embodiments, a portion of an orthographic projection of the second conductive connection portion N22 on the substrate 310 overlaps with an orthographic projection of the second electrode d8, the control electrode g8, and a portion of the first electrode s8 of the third reset transistor T8 on the substrate 310. Herein, the second electrode d8, the control electrode g8, and the first electrode s8 of the third reset transistor T8 may be sequentially disposed along the column direction Y. By making the orthographic projection of the second conductive connection portion N22 on the substrate 310 overlap with the orthographic projection of the second electrode d8, the control electrode g8 and a portion of the first electrode s8 of the third reset transistor T8 on the substrate 310, a width of the pixel driving circuit 211 in the row direction X may be reduced.

In some examples, a portion of the orthographic projection of the third reset transistor T8 on the substrate 310 and a portion of the orthographic projection of the first light-emitting control transistor T5 perpendicular to the substrate 310 are disposed opposite to each other in the row direction X, so that a width of the pixel driving circuit 211 in the row direction X may be reduced.

In some embodiments, the driving transistor T3, the data writing transistor T4, the first light-emitting control transistor T5 and the third reset transistor T8 are all located at a side of the first scanning signal line G-N where the second scanning signal line G-P is disposed. At this time, the driving transistor T3, the data writing transistor T4, the first light-emitting control transistor T5 and the third reset transistor T8 do not overlap with the first scanning signal line G-N. Therefore, the first electrode s3 of the driving transistor T3, the second electrode d4 of the data writing transistor T4, the second electrode d5 of the first light-emitting control transistor T5 and the second electrode d8 of the third reset transistor T8 electrically connected to the second conductive connection portion N22 do not overlap with the first scanning signal line G-N.

Herein, the voltages of the first electrode s3 of the driving transistor T3, the second electrode d4 of the data writing transistor T4, the second electrode d5 of the first light-emitting control transistor T5 and the second electrode d8 of the third reset transistor T8 may change with the second conductive connection portion N22. Therefore, when the voltages of the first electrode s3 of the driving transistor T3, the second electrode d4 of the data writing transistor T4, the second electrode d5 of the first light-emitting control transistor T5 and the second electrode d8 of the third reset transistor T8 change, the voltage fluctuation of the first scanning signal line G-N will also be caused. By making the first electrode s3 of the driving transistor T3, the second electrode d4 of the data writing transistor T4, the second electrode d5 of the first light-emitting control transistor T5 and the second electrode d8 of the third reset transistor T8 electrically connected to the second conductive connection portion N22 not overlap with the first scanning signal line G-N, the capacitances between the first electrode s3 of the driving transistor T3, the second electrode d4 of the data writing transistor T4, the second electrode d5 of the first light-emitting control transistor T5, the second electrode d8 of the third reset transistor T8 and the first scanning signal line G-N may be reduced. Therefore, when the voltage of the second conductive connection portion N22 changes, the voltage fluctuation of the first scanning signal line G-N may be reduced, thereby reducing the influence of the first scanning signal line G-N on the voltage of the first conductive connection portion N11, and further, improving the display effect of the display panel.

Please continue to refer to FIG. 14A and in combination with FIG. 13, in some embodiments, the pixel driving circuit 211 further includes a second light-emitting control transistor T6 and a second reset transistor T7.

The first electrode s6 of the second light-emitting control transistor T6 is electrically connected to the second electrode d3 of the driving transistor T3 and the first electrode s2 of the compensation transistor T2, and the second electrode d6 of the second light-emitting control transistor T6 is electrically connected to the light-emitting device 212 and the second electrode d7 of the second reset transistor T7.

Herein, control electrodes g6 of second light-emitting control transistors T6 of a row of pixel driving circuits 211 are electrically connected to a light-emitting control signal line Em, and thus a light-emitting control signal line Em may provide a light-emitting control signal EM for the control electrodes g6 of the second light-emitting control transistors T6 of the row of pixel driving circuits 211.

Control electrodes g7 of second reset transistors T7 of the row of pixel driving circuits 211 are electrically connected to a second reset signal line Rst-H, and thus the second reset signal line Rst-H may provide a second reset signal RST-H for the control electrodes g7 of the second reset transistors T7 of the row of pixel driving circuits 211.

The array substrate 300 further includes: a plurality of second initialization signal lines Vt2, where the plurality of second initialization signal lines Vt2 are located at a side of the plurality of pixel driving circuits 211 away from the substrate 310, and the plurality of second initialization signal lines Vt2 extend along the row direction X and are sequentially arranged along the column direction Y.

A second initialization signal line Vt2 is electrically connected to first electrodes s7 of second reset transistors T7 of a row of pixel driving circuits 211, and thus the second initialization signal provided by the second initialization signal line Vt2 may reset the first electrodes s7 of the second reset transistors T7 of the row of pixel driving circuits 211.

The second reset signal line Rst-H and the second initialization signal line Vt2 electrically connected to a row of pixel driving circuits 211 are both located in the row pixel region 301 (as shown in FIG. 12) where the row of pixel driving circuits 211 are located.

Herein, in the row pixel region 301 (as shown in FIG. 12): the orthographic projection of the second initialization signal line Vt2 on the substrate 310 is located at a side of the orthographic projection of the second reset signal line Rst-H on the substrate 310 away from the orthographic projection of the first scanning signal line G-N on the substrate 310.

Herein, the first electrode s7 and the second electrode d7 of the second reset transistor T7 may be located at both sides of the second reset signal line Rst-H in the column direction Y, respectively. For example, the orthographic projection of the first electrode s7 of the second reset transistor T7 on the substrate 310 may be located between the orthographic projection of the second reset signal line Rst-H on the substrate 310 and the orthographic projection of the second initialization signal line Vt2 on the substrate 310. With such configuration, the first electrode s7 of the second reset transistor T7 and the second initialization signal line Vt2 may be disposed adjacent to each other in the column direction Y, so that the first electrode s7 of the second reset transistor T7 and the second initialization signal line Vt2 may be electrically connected.

In some examples, the array substrate 300 may further include a fifth transfer portion 395, where the fifth transfer portion 395 may be electrically connected to the first electrode s7 of the second reset transistor T7 and the second initialization signal line Vt2, and then, the second initialization signal line Vt2 may be electrically connected to the first electrode s7 of the second reset transistor T7 through the fifth transfer portion 395.

Herein, the two ends of an orthographic projection of the fifth transfer portion 395 on the substrate 310 may overlap with an orthographic projection of the first electrode s7 of the second reset transistor T7 on the substrate 310 and an orthographic projection of the second initialization signal line Vt2 on the substrate 310, respectively.

In some examples, a portion of an orthographic projection of the second reset transistor T7 on the substrate 310 and a portion of an orthographic projection of the third reset transistor T8 on the substrate 310 are disposed opposite to each other in the row direction X. With such configuration, the size of the pixel driving circuit 211 in the column direction Y may be reduced.

Please continue to refer to FIG. 14A, and in combination with FIG. 13, in some embodiments, the pixel driving circuit 211 further includes: a first reset transistor T1 and a third conductive connection portion N33. Herein, the third conductive connection portion N33 is electrically connected to the second electrode d1 of the first reset transistor T1, the second electrode d3 of the driving transistor T3, the first electrode s2 of the compensation transistor T2, and the first electrode s6 of the second light-emitting control transistor T6.

The array substrate 300 further includes: a plurality of first reset signal lines Rst-P. The plurality of first reset signal lines Rst-P are located at a side of the plurality of pixel driving circuits 211 away from the substrate 310; the plurality of first reset signal lines Rst-P all extend along the row direction X and are sequentially arranged along the column direction Y, and a first reset signal line Rst-P is electrically connected to control electrodes g1 of first reset transistors T1 of a row of pixel driving circuits 211. In this way, a first reset signal line Rst-P may provide a first reset signal RST-P for the control electrodes g1 of the first reset transistors T1 of the row of pixel driving circuits 211.

The first reset signal line Rst-P to which the row of pixel driving circuits 211 is electrically connected is located in a row pixel region 301 (as shown in FIG. 12) where the row of pixel driving circuits 211 are located.

Herein, in the row pixel region 301 (as shown in FIG. 12): the orthographic projection of the first reset signal line Rst-P on the substrate 310 is located at a side of the orthographic projection of the light-emitting control signal line Em on the substrate 310 away from the orthographic projection of the first scanning signal line G-N on the substrate 310.

For example, in the row pixel region 301 (as shown in FIG. 12): the orthographic projection of the first reset signal line Rst-P on the substrate 310 is located at a side of the orthographic projection of the second reset signal line Rst-H on the substrate 310 away from the orthographic projection of the first light-emitting control signal line Em on the substrate 310.

Herein, a position of the first reset signal line Rst-P determines a position of the first reset transistor T1 in the pixel driving circuit 211. By making the first reset signal line Rst-P at a side of the light-emitting control signal line Em away from the first scanning signal line Em, the first reset transistor T1 and the compensation transistor T2 may be located at both sides of the first scanning signal line Em, respectively.

The orthographic projection of the first electrode s2 of the compensation transistor T2 on the substrate 310 is located at a side of the orthographic projection of the first scanning signal line G-N on the substrate 310 away from the orthographic projection of the light-emitting control signal line Em on the substrate 310. And the third conductive connection portion N33 may be electrically connected to the first electrode s2 of the compensation transistor T2 and the second electrode d2 of the first reset transistor T1. Therefore, the third conductive connection portion N33 may extend from a side of the first scanning signal line G-N in the column direction Y to the other side of the first scanning signal line G-N in the column direction Y. At this time, the third conductive connection portion N33 overlaps with the first scanning signal line G-N in a direction perpendicular to the substrate 310.

In addition, since the third conductive connection portion N33 is also electrically connected to the second electrode d3 of the driving transistor T3 and the first electrode s6 of the second light-emitting control transistor T6, the voltage of the second electrode d3 of the driving transistor T3, the voltage of the first electrode s1 of the second light-emitting control transistor T6 and the voltage of the third conductive connection portion N33 are equal.

It can be seen from some of the above embodiments that the orthographic projection of the driving transistor T3 on the substrate 310 and the orthographic projection of the second light-emitting control transistor T6 on the substrate 310 are both located at a side of the orthographic projection of the first scanning signal line G-N on the substrate 310 close to the orthographic projection of the light-emitting control signal line Em on the substrate 310. Therefore, the orthographic projection of the second electrode d3 of the driving transistor T3 on the substrate 310 and the orthographic projection of the first electrode s6 of the second light-emitting control transistor T6 on the substrate 310 are located at a side of the orthographic projection of the first scanning signal line G-N on the substrate 310 close to the orthographic projection of the light-emitting control signal line Em on the substrate 310. With such configuration, the second electrode d3 of the driving transistor T3 and the first electrode s6 of the second light-emitting control transistor T6 may be made not to overlap with the first scanning signal line G-N.

Therefore, when the voltage of the third conductive connection portion N33 suddenly changes, the influence on the voltage of the first scanning signal line G-N may be reduced.

In summary, in the third conductive connection portion N33, the second electrode d1 of the first reset transistor T1, the second electrode d3 of the driving transistor T3, the first electrode s2 of the compensation transistor T2 and the first electrode s6 of the second light-emitting control transistor T6, the third conductive connection portion N33 overlaps with the first scanning signal line G-N, and the second electrode d1 of the first reset transistor T1, the second electrode d3 of the driving transistor T3, the first electrode s2 of the compensation transistor T2 and the first electrode s1 of the second light-emitting control transistor T6 do no overlap with the first scanning signal line G-N, and thus, when the voltage of the third conductive connection portion N33 suddenly changes, the influence on the voltage of the first scanning signal line G-N may be reduced.

In some examples, the third conductive connection portion N33 may sequentially pass through the first electrode s2 of the compensation transistor T2, a connection of the second electrode d3 of the driving transistor T3 and the first electrode s6 of the second light-emitting control transistor T6, and the second electrode d1 of the first reset transistor T1 along the column direction Y.

In some examples, an orthographic projection of the second initialization signal line Vt2 on the substrate 310 overlaps with an orthographic projection of the first reset signal line Rst-P on the substrate 310. At this time, the orthographic projection of the second initialization signal line Vt2 on the substrate 310 and the orthographic projection of the first reset signal line Rst-P on the substrate 310 may partially overlap or completely overlap. With such configuration, the size of the pixel driving circuit 211 in the column direction Y is reduced.

Please continue to refer to FIG. 13 and FIG. 14A, in some embodiments, the array substrate 300 further includes a plurality of first initialization signal lines Vt1, where the plurality of first initialization signal lines Vt1 may be located at a side of the plurality of pixel driving circuits 211 away from the substrate 310. The plurality of first initialization signal line Vt1 all extend along the row direction X and are sequentially arranged along the column direction Y, and a first initialization signal line Vt1 is electrically connected to a first electrode s1 of a first reset transistor T1 of a row of pixel driving circuits 211.

Therefore, a first initialization signal line Vt1 may provide a first initialization signal for the first electrode s1 of the first reset transistor T1 of the row of pixel driving circuits 211.

The first initialization signal line Vt1 electrically connected to the row of pixel driving circuits 211 is located in a row pixel region 301 (as shown in FIG. 12) where the row of pixel driving circuits 211 are located.

Herein, in the row pixel region 301 (as shown in FIG. 12): the first initialization signal line Vt1 is located at a side of the first reset signal line Rst-P away from the first scanning signal line G-N.

In some embodiments, the first reset transistor T1 passes through a first reset signal line Rst-P. At this time, the orthographic projection of the first reset transistor T1 on the substrate 310 overlaps with the orthographic projection of the first reset signal line Rst-P on the substrate 310.

The first electrode s1 and the second electrode d1 of the first reset transistor T1 are located at both sides of the first reset signal line Rst-P in the column direction Y, respectively.

The orthographic projection of the first electrode s1 of the first reset transistor T1 on the substrate 310 is located between the orthographic projection of the first reset signal line Rst-P on the substrate 310 and the orthographic projection of the first initialization signal line Vt1 on the substrate 310. With such configuration, the first electrode s1 of the first reset transistor T1 may be disposed adjacent to the first initialization signal line Vt1, thereby facilitating an electrical connection between the first electrode s1 of the first reset transistor T1 and the first initialization signal line Vt1.

In some examples, the array substrate 300 may further include a first transfer portion 391, where the first transfer portion 391 may be electrically connected to the first electrode s1 of the first reset transistor T1 and the first initialization signal line Vt1, and then, the first initialization signal line Vt1 may be electrically connected to the first electrode s1 of the first reset transistor T1 through the first transfer portion 391. Herein, two ends of an orthographic projection of the first transfer portion 391 on the substrate 310 may overlap with an orthographic projection of the first electrode s1 of the first reset transistor T1 on the substrate 310 and an orthographic projection of the first initialization signal line Vt1 on the substrate 310, respectively.

The orthographic projection of the second electrode d1 of the first reset transistor T1 on the substrate 310 is located between the orthographic projection of the first reset signal line Rst-P on the substrate 310 and the orthographic projection of the second reset signal line Rst-H on the substrate 310. And the third conductive connection portion N33 may be electrically connected to the second electrode d1 of the first reset transistor T1, and thus a length of the third conductive connection portion N33 may be reduced.

In some examples, a portion of an orthographic projection of the first reset transistor T1 on the substrate 310 and a portion of an orthographic projection of the second reset transistor T7 on the substrate 310 are disposed opposite to each other in the row direction Y. With such configuration, the size of the pixel driving circuit 211 in the column direction Y may be reduced.

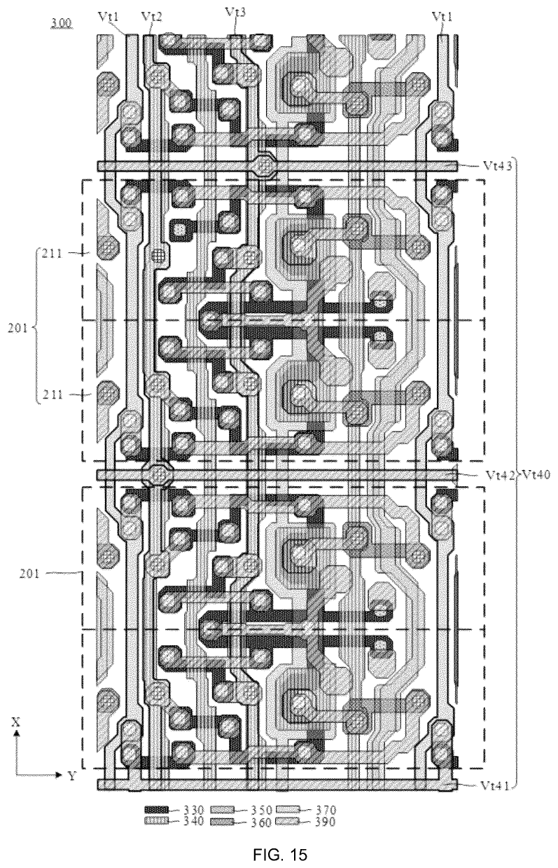

FIG. 15 is another structural schematic diagram of an array substrate 300 in accordance with some embodiments.

Please refer to FIG. 15, the array substrate 300 further includes: a plurality of auxiliary signal lines Vt40. The plurality of auxiliary signal lines Vt40 are located at a side of the substrate 310. For example, the plurality of auxiliary signal lines Vt40 may be located at a side of the pixel driving circuit 211 away from the substrate 310.

The plurality of auxiliary signal lines Vt40 all extend along the column direction Y and are sequentially arranged along the row direction X.

Herein, an auxiliary signal line Vt40 is electrically connected to any one of the first initialization signal line Vt1, the second initialization signal line Vt2 and the third initialization signal line Vt3.

For example, among the plurality of auxiliary signal lines Vt40, the auxiliary signal line Vt40 that may be electrically connected to the first initialization signal line Vt1 is a first auxiliary signal line Vt41.

Among the plurality of auxiliary signal lines Vt40, the auxiliary signal line Vt40 that may be electrically connected to the second initialization signal line Vt2 is a second auxiliary signal line Vt42.

Among the plurality of auxiliary signal lines Vt40, the auxiliary signal line Vt40 that may be electrically connected to the third initialization signal line Vt3 is a third auxiliary signal line Vt43.

In some embodiments, the plurality of auxiliary signal lines Vt40 may include any one or more of a first auxiliary signal line Vt41, a second auxiliary signal line Vt42, and a third auxiliary signal line Vt43.

By providing the first auxiliary signal line Vt41 electrically connected to the first initialization signal line Vt1, the first initialization signal line Vt1 and the first auxiliary signal line Vt41 may be interwoven into a mesh, thereby reducing the impedance of the first initialization signal line Vt1.

By providing the second auxiliary signal line Vt42 electrically connected to the second initialization signal line Vt2, the second initialization signal line Vt2 and the second auxiliary signal line Vt42 may be interwoven into a mesh, thereby reducing the impedance of the second initialization signal line Vt2.

By providing the third auxiliary signal line Vt43 electrically connected to the third initialization signal line Vt3, the third initialization signal line Vt3 and the third auxiliary signal line Vt43 may be interwoven into a mesh, thereby reducing the impedance of the third initialization signal line Vt3.

In some embodiments, the first auxiliary signal line Vt41, the second auxiliary signal line Vt42, and the third auxiliary signal line Vt43 may be cyclically arranged along the row direction X. For example, along the row direction X, the first auxiliary signal line Vt41, the second auxiliary signal line Vt42, the third auxiliary signal line Vt43, the first auxiliary signal line Vt41, the second auxiliary signal line Vt42 and the third auxiliary signal line Vt43 . . . and the first auxiliary signal line Vt41, the second auxiliary signal line Vt42 and the third auxiliary signal line Vt43 are sequentially disposed.

Herein, by making the first auxiliary signal line Vt41, the second auxiliary signal line Vt42 and the third auxiliary signal line Vt43 to be cyclically arranged along the row direction X, the first auxiliary signal line Vt41, the second auxiliary signal line Vt42 and the third auxiliary signal line Vt43 may be designed more regularly, thereby facilitating the fabrication of the array substrate 300.

Please continue to refer to FIG. 15, in some embodiments, a row of pixel driving circuits 211 are divided into a plurality of repeating units 201 sequentially disposed along the row direction X. Each repeating unit 201 includes at least one pixel driving circuit 211.

The auxiliary signal line Vt40 is located between two adjacent repeating units 201 in the row direction X.

Herein, a row of repeating units 201 are all located in the row pixel region 301 (as shown in FIG. 12).

One or more pixel driving circuits 211 may be disposed in a repeating unit 201.

For example, the repeating unit 201 includes two pixel driving circuits 211. At this time, the two pixel driving circuits 211 in the repeating unit 201 are symmetrically disposed in the row direction X.

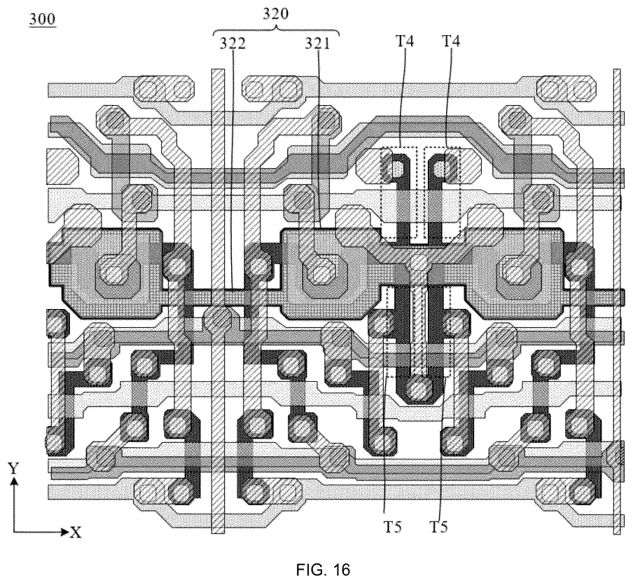

FIG. 16 is yet another structural diagram of an array substrate 300 in accordance with some embodiments.

Please refer to FIG. 16, in some embodiments, the array substrate 300 may further include a light shielding layer 320. The light shielding layer 320 is located between the substrate 310 and the pixel driving circuit 211. An orthographic projection of the light shielding layer 320 on the substrate 310 may cover an orthographic projection of the driving transistor T3 (as shown in FIG. 14A) on the substrate 310.

For example, the orthographic projection of the light shielding layer 320 on the substrate 310 may completely cover the orthographic projection of the driving transistor T3 on the substrate 310. At this time, the orthographic projection of the driving transistor T3 on the substrate 310 may be located in the region covered by the orthographic projection of the light shielding layer 320 on the substrate 310.

In some embodiments, the light shielding layer 320 includes a plurality of light shielding portions 321 and a plurality of connection portions 322, and the orthographic projections of the light shielding portions 321 on the substrate 310 cover the orthographic projections of the driving transistor T3 on the substrate 310.

Herein, two adjacent light shielding portions 321 in the row direction X are connected via a connection portion 322; and/or two adjacent light shielding portions 321 in the column direction Y are connected via a connection portion 322.

The light shielding layer 320 is configured to receive a first voltage signal.

Herein, by making the light shielding layer 320 receive the first voltage signal, the electrostatic accumulation generated by the light shielding layer 320 may be reduced.

And two adjacent light shielding portions 321 are connected via a connection portion 322, so that the impedance of the light shielding layer 320 may be reduced.

Next, each film layer of the array substrate 300 is introduced.

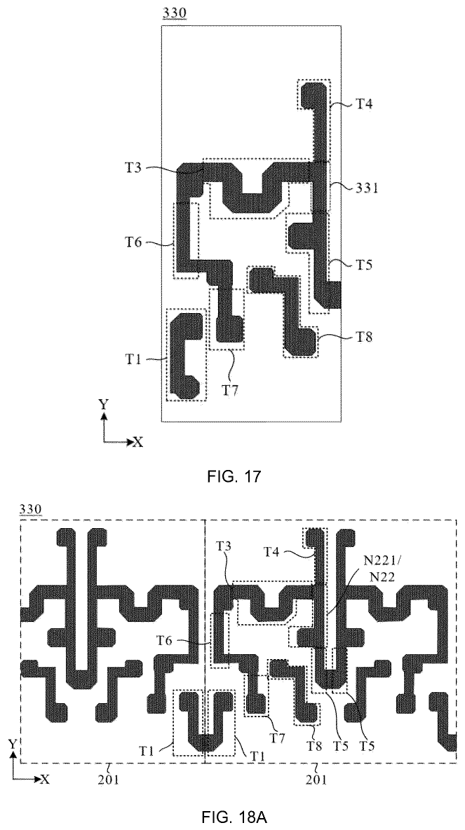

FIG. 17 is a structural diagram of a first active film layer 330 of an array substrate 300 in accordance with some embodiments.

Referring to FIG. 17, the array substrate 300 includes a first active film layer 330.

The first active film layer 330 may be used to form active layers of plurality of transistors in the pixel driving circuit 211, where an active layer of a transistor may include a channel region of the transistor, and a first electrode and a second electrode located at both sides of the channel region.

In some examples, the first active film layer 330 may be made of polysilicon material.

For example, the first active film layer 330 includes an active layer of a first reset transistor T1, an active layer of a driving transistor T3, an active layer of a data writing transistor T4, an active layer of a first light-emitting control transistor T5, an active layer of a second light-emitting control transistor T6, an active layer of a second reset transistor T77 and an active layer of a third reset transistor T8.

Herein, the active layer of the driving transistor T3 may be in a shape of Chinese character “A”. An end of the active layer of the driving transistor T3 is connected to the active layer of the second light-emitting control transistor T6, and the other end of the active layer of the driving transistor T3 is connected to the active layer of the data writing transistor T4 and the active layer of the first light-emitting control transistor T5.

A portion of the active layer of the data writing transistor T4 may extend in the column direction Y, and a portion of the active layer of the first light-emitting control transistor T5 may extend in the column direction Y.

An end of the active layer of the second light-emitting control transistor T6 away from the active layer of the driving transistor T3 is connected to the active layer of the second reset transistor T7.

A portion of the active layer of the third reset transistor T8 may be located between the active layer of the second reset transistor T7 and the active layer of the first light-emitting control transistor T5. An opening with a shape of Chinese character “A” and formed by the active layer of the driving transistor T3 may be away from the active layer of the third reset transistor T8.

An end of the active layer of the second reset transistor T7 away from the active layer of the second light-emitting control transistor T6 may be located between the active layer of the first reset transistor T1 and the active layer of the third reset transistor T8.

In some examples, the first active film layer 330 may further include an active connection portion 331, where the active connection portion 331 is connected to the active layer of the data writing transistor T4, the active layer of the first light-emitting control transistor T5, and the active layer of the driving transistor T3.

FIG. 18A is another structural diagram of a first active film layer 330 of an array substrate 300 in accordance with some embodiments. Herein in FIG. 18A, only a partial structure of the repeating unit 201 located on the left side is schematically shown.

Please refer to FIG. 18A, in some other embodiments, two first reset transistors T1 in a repeating unit 201 are respectively located at the two ends of the repeating unit 201 in the row direction X. That is, in a repeating unit 201, a first reset transistor T1 in a pixel driving circuit 211 is located at a position in the pixel driving circuit 211 and away from another pixel driving circuit 211. At this time, in two adjacent repetitive units 201 in the row direction X, the first reset transistors T1 are adjacently disposed.

The first electrodes s1 of two adjacent first reset transistors T1 in the row direction X may be electrically connected. At this time, two adjacent first reset transistors T1 in the row direction X share the first electrode s1. With such configuration, a width of the pixel driving circuit 211 in the row direction X may be reduced, which is beneficial to the high PPI (Pixels Per inch, pixel density) design of the display panel.

The first electrodes s5 of two adjacent first light-emitting control transistors T5 in the row direction X may be electrically connected.

FIG. 18B is a film layer stacking diagram of an array substrate 300 based on the first active film layer 330 in FIG. 18A. Herein, it should be noted that, in FIG. 18B, only a partial structure of the repeating unit 201 on the left side is schematically shown.

Please refer to FIG. 18B, the first electrode s1 of the first reset transistor T1 is electrically connected to the first initialization signal line Vt1. The array substrate 300 may further include a seventh transfer portion 397. The seventh transfer portion 397 is electrically connected to first electrodes s1 of two first reset transistors T1 through a via hole.

In some of the above embodiments, the first electrodes s1 of two adjacent first reset transistors T1 in the row direction X may be electrically connected. With such configuration, the first initialization signal line Vt1 may be electrically connected to the first electrodes s1 of the two first reset transistors T1 through a seventh transfer portion 397.

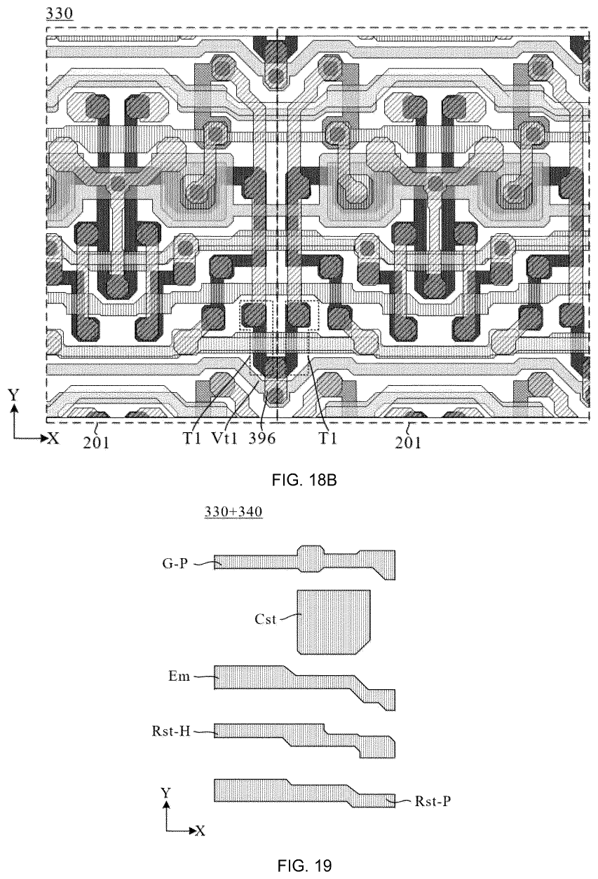

FIG. 19 is a structural diagram of a first gate metal layer of an array substrate 300 in accordance with some embodiments.

Please refer to FIG. 19, the array substrate 300 further includes a first gate metal layer 340, where the first gate metal layer 340 may be located at a side of the first active film layer 330 away from the substrate 310.

For example, the first gate metal layer 340 may include a second scanning signal line G-P, a light-emitting control signal line Em, a first reset signal line Rst-P, a second reset signal line Rst-H, and a first electrode of a capacitor Cst.

For example, the second scanning signal line G-P, the light-emitting control signal line Em, the first reset signal line Rst-P, and the second reset signal line Rst-H may be sequentially disposed along the column direction Y, and the first electrode of the capacitor Cst may be located between the second scanning signal line G-P and the light-emitting control signal line Em.

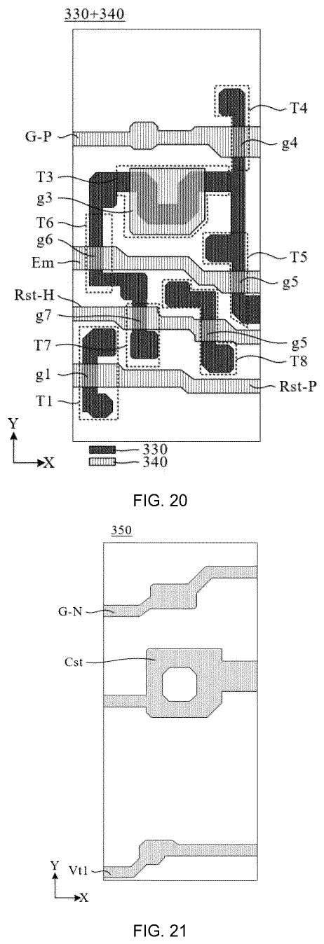

FIG. 20 is a structural diagram of a stacked arrangement of a first active film layer 330 and a first gate metal layer 340 in accordance with some embodiments.

Please refer to FIG. 20, an overlapping portion of the first gate metal layer 340 and the first active film layer 330 may be used as a control electrode of the transistor.

For example, a portion where the second scanning signal line G-P overlaps with the channel region of the data writing transistor T4 may be reused as the control electrode g4 of the data writing transistor T4.

The first electrode of the capacitor Cst is disposed to overlap with the channel region of the driving transistor T3, so the first electrode of the capacitor Cst may be reused as the control electrode g3 of the driving transistor T3.

A portion where the light-emitting control signal line Em and the channel region of the first light-emitting control transistor T5 overlap may be reused as the control electrode g5 of the first light-emitting control transistor T5, and a portion where the light-emitting control signal line Em and the channel region of the second light-emitting control transistor T6 overlap may be reused as the control electrode g6 of the second light-emitting control transistor T6.

A portion where the second reset signal line Rst-H and the channel region of the second reset transistor T7 overlap may be reused as the control electrode g7 of the second reset transistor T7, and a portion where the second reset signal line Rst-H and the channel region of the third reset transistor T8 overlap may be reused as the control electrode g8 of the third reset transistor T8.

FIG. 21 is a structural diagram of a second gate metal layer of an array substrate 300 in accordance with some embodiments.

Please refer to FIG. 21, the second gate metal layer 350 is located at a side of the first gate metal layer 340 away from the substrate 310, and the first gate metal layer 340 may include a first scanning signal line G-N, a second electrode of the capacitor Cst, and a first initialization signal line Vt1.

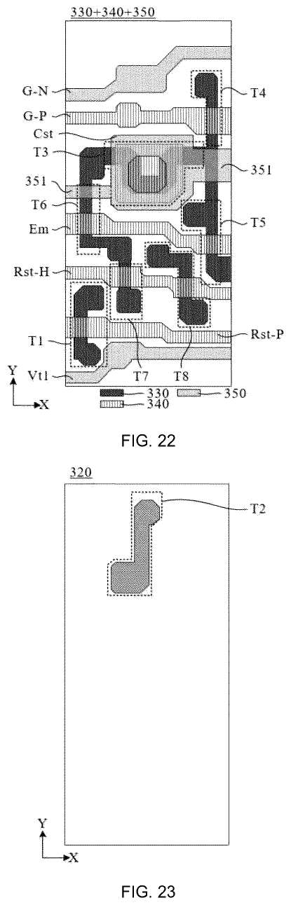

FIG. 22 is a structural diagram of a stacked arrangement of a first active film layer 330, a first gate metal layer 340 and a second gate metal layer 350 in accordance with some embodiments.

Please refer to FIG. 22, the second electrode of the capacitor Cst may be disposed to overlap with the first electrode of the capacitor Cst. And the second electrode of the capacitor Cst is provided with a via hole.

In some examples, the second gate metal layer 350 may further include an electrode connection portion 351, and the second electrodes of the capacitors Cst in two adjacent pixel driving circuits 211 in the row direction X may be electrically connected through the electrode connection portion 351, thereby reducing the impedance of the second electrode of the capacitor Cst.

FIG. 23 is a structural diagram of a second active film layer of an array substrate 300 in accordance with some embodiments.

Please refer to FIG. 23, the second active film layer 360 may be located at a side of the second gate metal layer 350 away from the substrate 310. The second active film layer 330 may include an active layer of the compensation transistor T2. Herein, the active layer of the compensation transistor T2 may include a first electrode, a channel region and a second electrode of the compensation transistor T2.

For example, the second active film layer 360 may be made of oxide, for example, the second active film layer 330 may be made of IGZO (Indium Gallium Zinc Oxide).

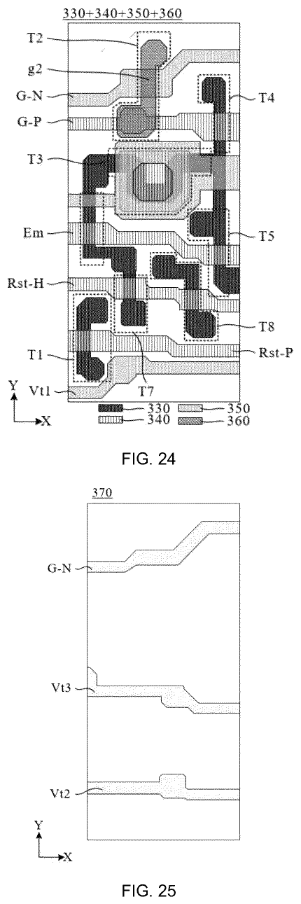

FIG. 24 is a structural diagram of a stacked arrangement of a first active film layer 330, a first gate metal layer 340, a second gate metal layer 350 and a second active film layer 360 in accordance with some embodiments.

Please refer to FIG. 24, the channel region of the compensation transistor T2 may be disposed to overlap with the second scanning signal line G-P, where a portion where the second scanning signal line G-P and the channel region of the compensation transistor T2 overlap may be reused as the control electrode g2 of the compensation transistor T2.

FIG. 25 is a structural diagram of a third gate metal layer of an array substrate 300 in accordance with some embodiments.

Please refer to FIG. 25, the third gate metal layer 370 is disposed at a side of the second active film layer 360 away from the substrate 310, where the third gate metal layer 370 may include a first scanning signal line G-N, a second initialization signal line Vt2, and a third initialization signal line Vt3.

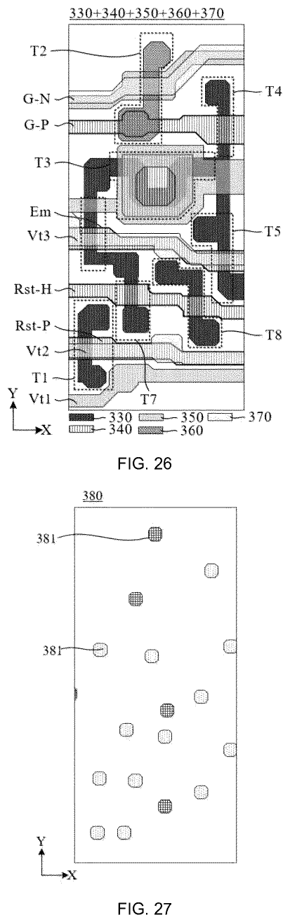

FIG. 26 is a structural diagram of a stacked arrangement of a first active film layer 330, a first gate metal layer 340, a second gate metal layer 350, a second active film layer 360 and a third gate metal layer 370 in accordance with some embodiments.

Please refer to FIG. 26, a portion where the first scanning signal line G-N in the third gate metal layer 370 and the active layer of the compensation transistor T2 overlap may be used as the control electrode of the compensation transistor T2. At this time, the compensation transistor T2 may be a double-gate transistor.

The first scanning signal line G-N in the third gate metal layer 370 may be disposed to overlap with the first scanning signal line G-N in the first gate metal layer 340.

The second initialization signal line Vt2 may be disposed to overlap with the second reset signal line Rst-H, and the third initialization signal line Vt3 may be disposed to overlapping with the light-emitting control signal line Em.

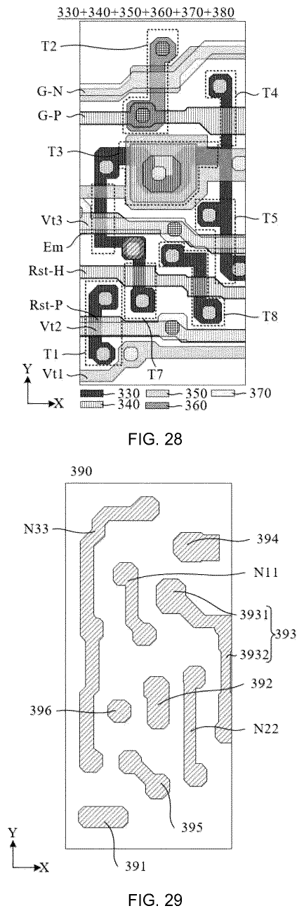

FIG. 27 is a structural diagram of an insulating layer of an array substrate 300 in accordance with some embodiments. FIG. 28 is a structural diagram of a stacked arrangement of a first active film layer 330, a first gate metal layer 340, a second gate metal layer 350, a second active film layer 360, a third gate metal layer 370 and an insulating layer 380 in accordance with some embodiments.

Please refer to FIG. 27 and FIG. 28, the insulating layer 380 is disposed at a side of the third gate metal layer 370 away from the substrate 310. Herein, the insulating layer 380 is provided with a plurality of via holes 381.

FIG. 29 is a structural diagram of a first source-drain metal layer of an array substrate 300 in accordance with some embodiments.

Please refer to FIG. 29, the first source-drain metal layer 390 is located at a side of the insulating layer 380 away from the substrate 310. The first source-drain metal layer 390 includes a first conductive connection portion N11, a second conductive connection portion N22, and a third conductive connection portion N33.

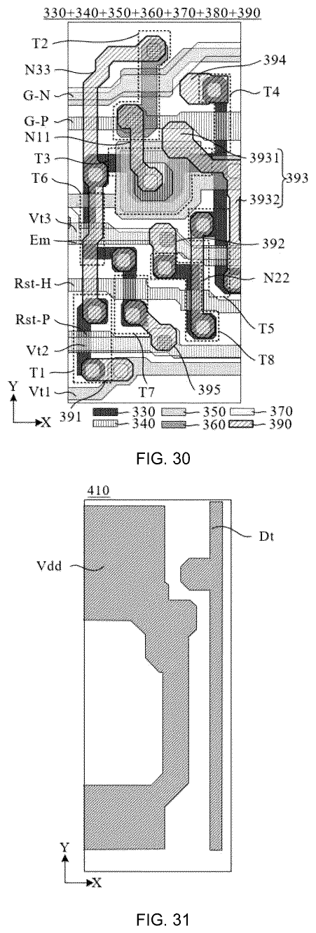

FIG. 30 is a structural diagram of a stacked arrangement of a first active film layer 330, a first gate metal layer 340, a second gate metal layer 350, a second active film layer 360, a third gate metal layer 370, an insulating layer 380 and a first source-drain metal layer 390 in accordance with some embodiments.

Please refer to FIG. 30, the first conductive connection portion N11 may be electrically connected to the control electrode g3 of the driving transistor T3 (as shown in FIG. 13) and the second electrode d2 of the compensation transistor T2 (as shown in FIG. 13) through a via hole 381 in the insulating layer 380.

The second conductive connection portion N22 may be electrically connected to the second electrode d5 of the first light-emitting control transistor T5 and the second electrode d8 of the third reset transistor T8 through the via hole 381 in the insulating layer 380, and the second electrode d5 of the first light-emitting control transistor T5 may also be electrically connected to the second electrode d4 of the data writing transistor T4 and the first electrode s3 of the driving transistor T3 through the active connection portion 331, so that the second conductive connection portion N22 may be electrically connected to the second electrode d4 of the data writing transistor T4 and the second electrode d5 of the first light-emitting control transistor T5, and the first electrode s3 of the driving transistor T3 and the second electrode d8 of the third reset transistor T8.

The third conductive connection portion N33 may be electrically connected to the second electrode d1 of the first reset transistor T1, the second electrode d3 of the driving transistor T3, the first electrode s2 of the compensation transistor T2, and the first electrode s6 of the second light-emitting control transistor T6 through the via hole 381 in the insulating layer 380.

In addition, the first source-drain metal layer 390 may include a first transfer portion 391, a second transfer portion 392, a third transfer portion 393, a data transfer portion 394, a fifth transfer portion 395 and a sixth transfer portion 396.

The first transfer portion 391 may be electrically connected to the first initialization signal line Vt1 and the first electrode s1 of the first reset transistor T1 through a via hole.

The second transfer portion 392 may be electrically connected to the first electrode s8 of the third reset transistor T8 and the third initialization signal line Vt3 through a via hole, so that the third initialization signal line Vt3 may be electrically connected to the first electrode s8 of the third reset transistor T8.

The third transition portion 393 may be electrically connected to the second gate metal layer 350 through a via hole and may also include an electrode connection portion 351 and a first electrode s5 of the first light-emitting control transistor T5. Since the electrode connection portion 351 is electrically connected to the second electrode of the capacitor Cst, the third transition portion 393 may be coupled to the second electrode of the capacitor Cst.

In some examples, the third transition portion 393 may include a first sub-connection portion 3931 and a second sub-connection portion 3932, where the first sub-connection portion 3931 may extend substantially along a first specified direction, where the first specified direction is parallel to the substrate 310 and intersects the row direction X and the column direction Y. The second sub-connection portion 3932 is connected to an end of the first sub-connection portion 3931. Herein, the orthographic projection of the first sub-connection portion 3931 on the substrate 310 is closer to the orthographic projection of the first scanning signal line G-N on the substrate 310 than the orthographic projection of the second sub-connection portion 3932 on the substrate 310.

The orthographic projection of the first sub-connection portion 3931 on the substrate 310 is closer to the orthographic projection of the third conductive connection portion N33 on the substrate 310 than the orthographic projection of the second sub-connection portion 3932 on the substrate 310.

For example, the second sub-connection portion 3932 away from the first sub-connection portion 3931 may be connected to the first electrode s5 of the first light-emitting control transistor T5 through a via hole.

Please refer back to FIG. 16, in some examples, within a repeating unit, the data writing transistors T4 in two pixel driving circuits 211 are adjacent in the row direction X, and the first light-emitting control transistors T5 in two pixel driving circuits 211 are adjacent in the row direction X. The third transition portion 393 electrically connected to the first electrode s5 of the first light-emitting control transistor T5 in the two pixel driving circuits 211 shares the second sub-connection part 3932. At this time, the first sub-connection portion 3931 electrically connected to the first electrodes s5 of the first light-emitting control transistors T5 in the two pixel driving circuits 211 is electrically connected to the same second sub-connection portion 3932. A second sub-connection portion 3932 may be electrically connected to the first electrodes s5 of the first light-emitting control transistors T5 in two pixel driving circuits 211 in a repeating unit.

Please continue to refer to FIG. 30, the data transfer portion 394 may be electrically connected to the first electrode s4 of the data writing transistor T4 through a via hole.

The fifth transfer portion 395 may be electrically connected to the first electrode s7 of the second reset transistor T7 and the second initialization signal line Vt2 through a via hole, so that the second initialization signal line Vt2 may be electrically connected to the first electrode s7 of the second reset transistor T7.

The sixth transfer portion 396 may be electrically connected to the second electrode d6 of the second light-emitting control transistor T6 and the second electrode d7 of the second reset transistor T7 through a via hole. Herein, the sixth transfer portion 396 may also be electrically connected to the light-emitting device 212, so that the light-emitting device 212 may be electrically connected to the second electrode d6 of the second light-emitting control transistor T6 and the second electrode d7 of the second reset transistor T7 through the sixth transfer portion 396.

Please refer to FIG. 15 again, in some embodiments, the first source-drain metal layer 390 may also include a plurality of auxiliary signal lines Vt40. For example, the plurality of auxiliary signal lines Vt40 may include any one or more of a first auxiliary signal line Vt41, a second auxiliary signal line Vt42, and a third auxiliary signal line Vt43.

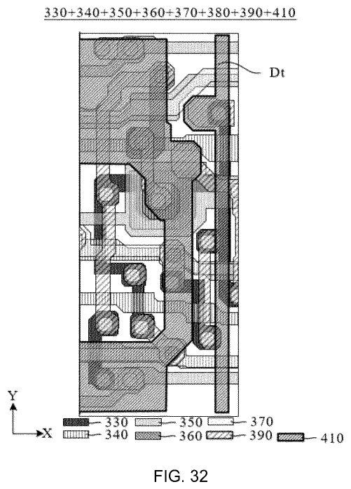

FIG. 31 is a structural diagram of a second source-drain metal layer of an array substrate 300 in accordance with some embodiments. FIG. 32 is a structural diagram of a stacked arrangement of a first active film layer 330, a first gate metal layer 340, a second gate metal layer 350, a second active film layer 360, a third gate metal layer 370, an insulating layer 380, a first source-drain metal layer 390 and a second source-drain metal layer in accordance with some embodiments.

Please refer to FIG. 31, the second source-drain metal layer 410 is located at a side of the first source-drain metal layer 390 away from the substrate. The second source-drain metal layer 410 may include a first power signal line Vdd and a data line Dt.

Herein, the first power signal line Vdd may be electrically connected to the third transition portion 393, and the third transition portion 393 is further electrically connected to the first electrode s5 of the first light-emitting control transistor T5 and the second electrode of the capacitor Cst, then the first power signal line Vdd may provide the first power signal to the second electrode of the capacitor Cst and the first electrode s5 of the first light-emitting control transistor T5 through the third transition portion 393.

For example, the first power signal line Vdd may be connected to an end of the first sub-connection portion 3931 away from the second sub-connection portion 3932 through a via hole.

The data line Dt may be electrically connected to the data transfer portion 394, so that the data line Dt may provide a data signal to the first electrode s4 of the data writing transistor T4 through the data transfer portion 394.

In the present disclosure, a display panel using the array substrate 300 provided in FIG. 31 is tested. After testing, the capacitance value between the second conductive connection portion N22 and the first scanning signal line G-N is 0, and the capacitance value between the third conductive connection portion N33 and the first scanning signal line is 2.859 fF.

In the related art, the capacitance value between the second conductive connection portion N22 and the first scanning signal line G-N is 1.829 fF, and the capacitance value between the third conductive connection portion N33 and the first scanning signal line is 3.340 fF.

By comparison, it can be seen that compared with the related art, the present disclosure can effectively reduce the capacitance value between the second conductive connection portion N22 and the first scanning signal line G-N, and the capacitance value between the third conductive connection portion N33 and the first scanning signal line.

In some of the above embodiments, the film layer structure of “8T1C” pixel driving circuit is introduced, and in some other embodiments, the “8T1C” pixel driving circuit may also have different film layer structures, which are not introduced one by one herein.

The above are only specific implementations of the present disclosure, but the scope of protection of the present disclosure is not limited thereto. Variations or replacements thought by any person skilled in the art within the technical scope of the present disclosure shall fall within the protection scope of the present disclosure. Therefore, the protection scope of the present disclosure should be determined by the protection scope of the claims.

1. An array substrate, comprising:
a substrate;
a plurality of pixel driving circuits, located at a side of the substrate, and arranged in multiple rows and multiple columns; a pixel driving circuit of the plurality of pixel driving circuits comprises a compensation transistor, a driving transistor and a first conductive connection portion, wherein a control electrode of the driving transistor and a second electrode of the compensation transistor are both electrically connected to the first conductive connection portion;
a plurality of first scanning signal lines, located at a side of the substrate, wherein the plurality of first scanning signal lines are extended along a row direction and are sequentially arranged along a column direction, the row direction and the column direction are parallel to the substrate and cross-arranged; a first scanning signal line of the plurality of first scanning signal lines is electrically connected to control electrodes of compensation transistors of a row of pixel driving circuits;
wherein the first conductive connection portion and the first scanning signal line do not overlap in a direction perpendicular to the substrate.

2. The array substrate according to claim 1, wherein
the pixel driving circuit further comprises: a data writing transistor and a first light-emitting control transistor, wherein a second electrode of the data writing transistor is electrically connected to a first electrode of the driving transistor and a second electrode of the first light-emitting control transistor;
the array substrate further comprises: a plurality of second scanning signal lines and a plurality of light-emitting control signal lines, located at a side of the substrate; the plurality of second scanning signal lines all extend along the row direction and are sequentially arranged along the column direction, and a second scanning signal line of plurality of second scanning signal lines is electrically connected to control electrodes of data writing transistors of the row of pixel driving circuits; the plurality of light-emitting control signal lines all extend along the row direction and are sequentially arranged along the column direction, and a light-emitting control signal line of the plurality of light-emitting control signal lines is electrically connected to control electrodes of first light-emitting control transistors of the row of pixel driving circuits;
the array substrate further comprises: a plurality of row pixel regions, wherein the plurality of row pixel regions extend along the row direction and are sequentially disposed along the column direction; the row of pixel driving circuits are disposed within a row pixel region of the plurality of row pixel regions, and a first scanning signal line, a second scanning signal line and a light-emitting control signal line electrically connected to the row of pixel driving circuits are located in the row pixel region where the row of pixel driving circuits are located;
wherein in the row pixel region: an orthographic projection of the first scanning signal line on the substrate is located at a side of an orthographic projection of the second scanning signal line on the substrate away from an orthographic projection of the light-emitting control signal line on the substrate, and an orthographic projection of the driving transistor on the substrate is located between the orthographic projection of the second scanning signal line on the substrate and the orthographic projection of the light-emitting control signal line on the substrate.

3. The array substrate according to claim 2, wherein
in the row pixel region, the compensation transistor and the first conductive connection portion are sequentially disposed along the column direction; wherein the compensation transistor passes through the first scanning signal line, and an orthographic projection of the second electrode of the compensation transistor on the substrate is located at a side of an orthographic projection of the first scanning signal line on the substrate close to the orthographic projection of the light-emitting control signal line on the substrate, wherein the first conductive connection portion is located at a side of the first scanning signal line close to the light-emitting control signal line.

4. The array substrate according to claim 3, wherein
in the row pixel region, a portion of an orthographic projection of the data writing transistor on the substrate is disposed opposite to an orthographic projection of the compensation transistor on the substrate in the row direction, and another portion of the orthographic projection of the data writing transistor on the substrate is disposed opposite to an orthographic projection of the first conductive connection portion on the substrate in the row direction.

5. The array substrate according to claim 4, wherein
the data writing transistor passes through the second scanning signal line, and the data writing transistor is located at a side of the first scanning signal line close to the light-emitting control signal line;
the array substrate further comprises:
a plurality of data transfer portions, wherein the plurality of data transfer portions are located at a side of the plurality of pixel driving circuits away from the substrate;
a plurality of data lines, wherein the plurality of data lines are located at a side of the plurality of data transfer portions away from the substrate, the plurality of data lines extend along the column direction and are sequentially arranged along the row direction, and a data line of the plurality of data lines is electrically connected to first electrodes of data writing transistors of the row of pixel driving circuits through a data transfer portion of the plurality of data transfers portions;
wherein in the row pixel region, an orthographic projection of the data transfer portion on the substrate is located between the orthographic projection of the first scanning signal line on the substrate and the orthographic projection of the second scanning signal line on the substrate.

6. The array substrate according to claim 3, wherein
in the row pixel region, a portion of an orthographic projection of the first conductive connection portion on the substrate overlaps with a portion of an orthographic projection of the compensation transistor on the substrate, and another portion of the orthographic projection of the first conductive connection portion on the substrate overlaps with a portion of the orthographic projection of the driving transistor on the substrate.

7. The array substrate according to claim 2, wherein
the pixel driving circuit further comprises a second conductive connection portion, wherein the second conductive connection portion is electrically connected to the first electrode of the driving transistor, the second electrode of the first light-emitting control transistor, and a second electrode of the data writing transistor;
an orthographic projection of the second conductive connection portion on the substrate does not overlap with an orthographic projection of the first scanning signal line on the substrate.

8. The array substrate according to claim 7, wherein
the pixel circuit further comprises a third reset transistor, wherein a second electrode of the third reset transistor is electrically connected to the second conductive connection portion;
the array substrate further comprises: a plurality of second reset signal lines, wherein the plurality of second reset signal lines are located at a side of the plurality of pixel driving circuits away from the substrate, the plurality of second reset signal lines all extend along the row direction, and sequentially arrange along the column direction; a second reset signal line of the plurality of second reset signal lines is electrically connected to control electrodes of third reset transistors of the row of pixel driving circuits; the second reset signal line electrically connected to the row of pixel driving circuits is located in the row pixel region where the row of pixel driving circuits are located;
wherein in the row pixel region, the second reset signal line is located at a side of the light-emitting control signal line away from the first scanning signal line.

9. The array substrate according to claim 8, further comprising:
a plurality of third initialization signal lines, located at a side of the substrate; the plurality of third initialization signal lines all extend along the row direction and are sequentially arranged along the column direction, and a third initialization signal line of the plurality of third initialization signal lines is electrically connected to first electrodes of third reset transistors of the row of pixel driving circuits;
in the row pixel region: an orthographic projection of the third initialization signal line on the substrate at least partially overlaps with the orthographic projection of the light-emitting control signal line on the substrate.

10. The array substrate according to claim 9, wherein
in the row pixel region: the third reset transistor passes through the second reset signal line and is located at a side of the third initialization signal line away from the light-emitting control signal line; wherein an orthographic projection of a first electrode of the third reset transistor on the substrate is located between an orthographic projection of the third initialization signal line on the substrate and an orthographic projection of the second reset signal line on the substrate, and an orthographic projection of the second electrode of the third reset transistor on the substrate is located at a side of an orthographic projection of the second reset signal line on the substrate away from the orthographic projection of the third initialization signal line on the substrate;
the second conductive connection portion crosses over the third initialization signal line, the light-emitting control signal line, and the second reset signal line, and is electrically connected to the second electrode of the third reset transistor.

11. The array substrate according to claim 10, wherein
a portion of the orthographic projection of the second conductive connection portion on the substrate overlaps with an orthographic projection of the second electrode, a control electrode, and a portion of the first electrode of the third reset transistor on the substrate.

12. The array substrate according to claim 9, wherein
the pixel driving circuit further comprises a second light-emitting control transistor and a second reset transistor; a first electrode of the second light-emitting control transistor is electrically connected to a second electrode of the driving transistor and a first electrode of the compensation transistor, and a second electrode of the second light-emitting control transistor is electrically connected to a light-emitting device and a second electrode of the second reset transistor; wherein control electrodes of second light-emitting control transistors of the row of pixel driving circuits are electrically connected to the light-emitting control signal line, and control electrodes of second reset transistors of the row of pixel driving circuits are electrically connected to the second reset signal line;
the array substrate further comprises: a plurality of second initialization signal lines, wherein the plurality of second initialization signal lines are located at a side of the plurality of pixel driving circuits away from the substrate, the plurality of second initialization signal lines extend along the row direction, and are sequentially arranged along the column direction; a second initialization signal line of the plurality of second initialization signal lines is electrically connected to first electrodes of second reset transistors of the row of pixel driving circuits;
wherein in the row pixel region, an orthographic projection of the second initialization signal line on the substrate is located at a side of an orthographic projection of the second reset signal line on the substrate away from the orthographic projection of the first scanning signal line on the substrate.

13. The array substrate according to claim 12, wherein
the pixel driving circuit further comprises: a first reset transistor and a third conductive connection portion, wherein the third conductive connection portion is electrically connected to a second electrode of the first reset transistor, the second electrode of the driving transistor and the first electrode of the compensation transistor;
the array substrate further comprises: a plurality of first reset signal lines, wherein the plurality of first reset signal lines are located at a side of the plurality of pixel driving circuits away from the substrate; the plurality of first reset signal lines all extend along the row direction and are sequentially arranged along the column direction, and a first reset signal line of the plurality of first reset signal lines is electrically connected to control electrodes of first reset transistors of the row of pixel driving circuits;
wherein in the row pixel region, an orthographic projection of the first reset signal line on the substrate is located at a side of an orthographic projection of the light-emitting control signal line on the substrate away from the orthographic projection of the first scanning signal line on the substrate.

14. The array substrate according to claim 13, further comprising:
a plurality of first initialization signal lines, located at a side of the plurality of pixel driving circuits away from the substrate, wherein the plurality of first initialization signal lines all extend along the row direction and are sequentially arranged along the column direction, and a first initialization signal line of the plurality of first initialization signal lines is electrically connected to first electrodes of first reset transistors of the row of pixel driving circuits;
wherein in the row pixel region, the first initialization signal line is located at a side of the first reset signal line away from the first scanning signal line.

15. The array substrate according to claim 14, wherein
the first reset transistor passes through the first reset signal line, an orthographic projection of a first electrode of the first reset transistor on the substrate is located between the orthographic projection of the first reset signal line on the substrate and an orthographic projection of the first initialization signal line on the substrate, and an orthographic projection of the second electrode of the first reset transistor on the substrate is located between the orthographic projection of the first reset signal line on the substrate and the orthographic projection of the second reset signal line on the substrate.

16. The array substrate according to claim 14, wherein
the orthogonal projection of the first reset signal line on the substrate overlaps with the orthogonal projection of the second initialization signal line on the substrate.

17. The array substrate according to claim 14, further comprising:
a plurality of auxiliary signal lines, located at a side of the substrate, wherein the plurality of auxiliary signal lines all extend along the column direction and are sequentially arranged along the row direction;
wherein an auxiliary signal line of the plurality of auxillary signal lines is electrically connected to any one of the first initialization signal line, the second initialization signal line and the third initialization signal line.

18. The array substrate according to claim 17, wherein
the row of pixel driving circuits is divided into a plurality of repeating units sequentially disposed along the row direction, wherein a repeating unit of the plurality of repeating units comprises at least one of the row of pixel driving circuits;
the auxiliary signal line is located between two adjacent repeating units in the row direction; or
the row of pixel driving circuits is divided into a plurality of repeating units sequentially disposed along the row direction, wherein a repeating unit of the plurality of repeating units comprises at least one of the row of pixel driving circuits; the auxiliary signal line is located between two adjacent repeating units in the row direction, and the repeating unit includes two pixel driving circuits, and the two pixel driving circuits in the repeating unit are symmetrically disposed in the row direction; or
the plurality of auxillary signal lines include a first auxillary signal line, a second auxillary signal line and a third auxiliary signal line, the first auxillary signal line is electrically connected to the first initialization signal line, the second auxillary signal line is electrically connected to the second initialization signal line, and the third auxiliary signal line is electrically connected to the third initialization signal line.

19. (canceled)

20. (canceled)

21. A display panel, comprising:
the array substrate according to claim 1;
a light-emitting device layer, located at a side of the array substrate away from the substrate, and
an encapsulation layer, located at a side of the light-emitting device layer away from the array substrate.

22. A display device, comprising:
the display panel according to claim 21;
a driving chip, electrically connect to the display panel.
